(19) United States
(12) Patent Application Publication
(10) Pub. No.: US 2025/0221189 A1
(43) Pub. Date: Jul. 3, 2025

(54) DISPLAY APPARATUS

(71) Applicant: LG Display Co., Ltd., Seoul (KR)

(72) Inventors: JongSeok KIM, Paju-si (KR); Seokgi KIM, Paju-si (KR); Jinhong LIM, Paju-si (KR)

(73) Assignee: LG Display Co., Ltd., Seoul (KR)

(21) Appl. No.: 18/679,073

(22) Filed: May 30, 2024

(30) Foreign Application Priority Data
Dec. 29, 2023 (KR) 10-2023-0196990

(51) Int. Cl. H10K 59/131

(52) U.S. Cl. CPC H10K 59/131

(57) ABSTRACT

Discussed is a display apparatus including a substrate including a display area having a plurality of subpixels, a first data line disposed at the display area and extending in a column direction, a first link line disposed at the display area, electrically connected to the first data line, and extending in a row direction, a second link line disposed in the display area and extending in the column direction, a first metal pattern spaced apart from the first link line and extending in the row direction, and a second metal pattern spaced apart from the second link line and extending in the column direction.

### CROSS-REFERENCE TO RELATED APPLICATION

This application claims priority to Republic of Korea Patent Application No. 10-2023-0196990, filed on Dec. 29, 2023 in the Korean Intellectual Property Office, the entire contents of which is hereby expressly incorporated by reference into the present application.

### BACKGROUND

### Field

The present disclosure relates to a display apparatus, and more specifically, to a display apparatus including a data link structure.

### Discussion of the Related Art

A display apparatus can include a display area configured to allow an image to be displayed and a non-display area that does not display an image. In order for the display apparatus to perform various functionalities such as displaying the image, sensing a touch event, and the like, various structures, circuits, lines, and the like can be disposed in the non-display area, which can also be referred to as a “non-active area” or “bezel” of a display panel.

### SUMMARY OF THE DISCLOSURE

To meet market demands for a large display area, it would be desirable to reduce the bezel size of a display panel. However, since elements necessary for operation of the display panel are disposed in the non-display area, it is not easy to reduce the bezel size. In particular, link lines for delivering data signals to data lines can be disposed in the non-display area of a display panel, and thereby, reducing the bezel size of the display panel can be problematic.

One or more aspects of the present disclosure can provide a display apparatus with a data link structure capable of reducing the bezel size of a display panel.

One or more aspects of the present disclosure can provide a display apparatus with a bezel reduction data link structure capable of improving image quality.

One or more aspects of the present disclosure can provide a display apparatus with a bezel reduction data link structure capable of improving the performance of transmitting a common driving voltage.

One or more aspects of the present disclosure can provide a display apparatus with a bezel reduction data link structure capable of reducing a difference in reflected light.

According to aspects of the present disclosure, a display apparatus can include a substrate including a display area having a plurality of subpixels, a first data line disposed at the display area and extending in a column direction, a first link line disposed at the display area, electrically connected to the first data line, and extending in a row direction, a second link line disposed at the display area and extending in the column direction, a first metal pattern spaced apart from the first link line and extending in the row direction, and a second metal pattern spaced apart from the second link line and extending in the column direction.

According to aspects of the present disclosure, a display apparatus can include a substrate, a first signal line disposed on the substrate and extending in a first direction, a first power line including a same first metal as the first signal line and spaced apart from the first signal line, a second signal line disposed on the substrate and extending in a second direction different from the first direction, and a second power line including a same second metal as the second signal line and spaced apart from the second signal line.

According to one or more aspects of the present disclosure, a display apparatus can be provided with a data link structure capable of reducing the bezel of a display panel.

According to one or more aspects of the present disclosure, a display apparatus can be provided with a bezel reduction data link structure capable of improving image quality.

According to one or more aspects of the present disclosure, a display apparatus can be provided with a bezel reduction data link structure capable of improving the performance of transmitting a common driving voltage.

According to one or more aspects of the present disclosure, a display apparatus can be provided with a bezel reduction data link structure capable of reducing a difference in reflected light.

According to one or more aspects of the present disclosure, a display apparatus and/or a display panel can be provided with a reduced weight by reducing the bezel of the display panel using an improved data link structure.

### BRIEF DESCRIPTION OF THE DRAWINGS

The accompanying drawings, which are included to provide a further understanding of the disclosure, are incorporated in and constitute a part of the disclosure, illustrate aspects of the disclosure and together with the description serve to explain principles of the disclosure.

FIG. 1 illustrates a system configuration of a display apparatus according to aspects of the present disclosure.

FIG. 2 illustrates a display panel according to aspects of the present disclosure.

FIG. 3 is a cross-sectional view of the display panel according to aspects of the present disclosure.

FIG. 4 illustrates a substrate of the display panel according to aspects of the present disclosure.

FIG. 5 is a plan view of the display panel according to aspects of the present disclosure and illustrates a data link structure configured in the display panel.

FIG. 6 is another plan view of the display panel according to aspects of the present disclosure and illustrates an example data link structure capable reducing the bezel of the display panel.

FIG. 7 illustrates three areas defined in a display area of the display panel according to aspects of the present disclosure.

FIG. 8 illustrates some areas of the display panel according to aspects of the present disclosure.

FIG. 9 is a cross-sectional view illustrating a first open area of a first metal layer of the display panel according to aspects of the present disclosure.

FIG. 10 is a cross-sectional view illustrating a second open area of a second metal layer of the display panel according to aspects of the present disclosure.

FIG. 11 illustrates a structure capable of reducing a difference in reflected light associated with the bezel reduction data link structure in the display panel according to aspects of the present disclosure.

FIGS. 12 to 14 illustrate shielding structures configured in a first open area of a first metal layer of the display panel according to aspects of the present disclosure.

FIG. 15 illustrates a shielding structure configured in the second open area of the second metal layer of the display panel according to aspects of the present disclosure.

### DETAILED DESCRIPTIONS OF THE EMBODIMENTS

Reference is now made in detail to aspects of the present disclosure, examples of which can be illustrated in the accompanying drawings. In the following description, when a detailed description of well-known methods, functions, structures or configurations can unnecessarily obscure aspects of the present disclosure, a detailed description of such known functions or configurations can be omitted for brevity. Further, repetitive descriptions can be omitted for brevity. The progression of processing steps and/or operations described is a non-limiting example.

The sequence of steps and/or operations is not limited to that set forth herein and can be changed to occur in an order that is different from an order described herein, with the exception of steps and/or operations necessarily occurring in a particular order. In one or more examples, two operations in succession can be performed substantially concurrently, or the two operations can be performed in a reverse order or in a different order depending on a function or operation involved.

Unless stated otherwise, like reference numerals can refer to like elements throughout even when they are shown in different drawings. Unless stated otherwise, the same reference numerals may be used to refer to the same or substantially the same elements throughout the specification and the drawings. In one or more aspects, identical elements (or elements with identical names) in different drawings can have the same or substantially the same functions and properties unless stated otherwise. Names of the respective elements used in the following explanations are selected only for convenience and can be thus different from those used in actual products.

Advantages and features of the present disclosure, and implementation methods thereof, are clarified through the aspects described with reference to the accompanying drawings. The present disclosure may, however, be embodied in different forms and should not be construed as limited to the example aspects set forth herein. Rather, these example aspects are examples and are provided so that this disclosure can be thorough and complete to assist those skilled in the art to understand the inventive concepts without limiting the protected scope of the present disclosure.

Shapes, dimensions (e.g., sizes, lengths, widths, heights, thicknesses, locations, radii, diameters, and areas), proportions, ratios, angles, numbers, the number of elements, and the like disclosed herein, including those illustrated in the drawings, are merely examples, and thus, the present disclosure is not limited to the illustrated details. It is, however, noted that the relative dimensions of the components illustrated in the drawings are part of the present disclosure.

Where a term like “comprise,” “have,” “include,” “contain,” “constitute,” “made of,” “formed of,” “composed of,” or the like is used with respect to one or more elements (e.g., layers, films, regions, components, sections, members, parts, regions, areas, portions, steps, operations, and/or the like), one or more other elements can be added unless a term, such as “only” or the like is used. The terms used in the present disclosure are merely used in order to describe example aspects, and are not intended to limit the scope of the present disclosure. The terms of a singular form can include plural forms unless the context clearly indicates otherwise.

The word “exemplary” is used to mean serving as an example or illustration, unless otherwise specified. Embodiments are example embodiments. Aspects are example aspects. In one or more implementations, “embodiments,” “aspects,” “examples,” and the like should not be construed to be preferred or advantageous over other implementations. An aspect, an example, an example aspect, or the like can refer to one or more aspects, one or more examples, one or more example aspects, or the like, unless stated otherwise. Further, the term “may” encompasses all the meanings of the term “can.”

In one or more aspects, unless explicitly stated otherwise, an element, feature, or corresponding information (e.g., a level, range, dimension, size, or the like) is construed to include an error or tolerance range even where no explicit description of such an error or tolerance range is provided. An error or tolerance range can be caused by various factors (e.g., process factors, internal or external impact, noise, or the like). In interpreting a numerical value, the value is interpreted as including an error range unless explicitly stated otherwise.

In describing a positional relationship when the positional relationship between two parts (e.g., layers, films, regions, components, sections, or the like) is described, for example, using “on,” “upon,” “on top of,” “over,” “under,” “above,” “below,” “beneath,” “near,” “close to,” “adjacent to,” “beside,” “next to,” “at or on a side of,” or the like, one or more other parts can be located between the two parts unless a more limiting term, such as “immediate(ly),” “direct(ly),” or “close(ly),” is used. For example, where a structure is described as being positioned “on,” “upon,” “on top of,” “over,” “under,” “above,” “below,” “beneath,” “near,” “close to,” “adjacent to,” “beside,” “next to,” “at or on a side of,” or the like another structure, this description should be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference.

Spatially relative terms, such as “below,” “beneath,” “lower,” “on,” “above,” “upper” and the like, can be used to describe a correlation between various elements (e.g., layers, films, regions, components, sections, or the like) as shown in the drawings. The spatially relative terms are to be understood as terms including different orientations of the elements in use or in operation in addition to the orientation depicted in the drawings. For example, if the elements shown in the drawings are turned over, elements described as “below” or “beneath” other elements would be oriented “above” other elements. Thus, the term “below,” which is an example term, can include all directions of “above” and “below.” Likewise, an exemplary term “above” or “on” can include both directions of “above” and “below.”

In describing a temporal relationship, when the temporal order is described as, for example, “after,” “subsequent,” “next,” “before,” “preceding,” “prior to,” or the like, a case that is not consecutive or not sequential can be included and thus one or more other events can occur therebetween, unless a more limiting term, such as “just,” “immediate(ly),” or “direct(ly),” is used.

The terms, such as “below,” “lower,” “above,” “upper” and the like, can be used herein to describe a relationship between element(s) as illustrated in the drawings. It will be understood that the terms are spatially relative and based on the orientation depicted in the drawings.

It is understood that, although the terms “first,” “second,” or the like can be used herein to describe various elements (e.g., layers, films, regions, components, sections, members, parts, regions, areas, portions, steps, operations, and/or the like), these elements should not be limited by these terms, for example, to any particular order, precedence, or number of elements. These terms are used only to distinguish one element from another. For example, a first element could be termed a second element, and, similarly, a second element could be termed a first element, without departing from the scope of the present disclosure. Furthermore, the first element, the second element, and the like can be arbitrarily named according to the convenience of those skilled in the art without departing from the scope of the present disclosure. For clarity, the functions or structures of these elements (e.g., the first element, the second element and the like) are not limited by ordinal numbers or the names in front of the elements. Further, a first element can include one or more first elements. Similarly, a second element or the like can include one or more second elements or the like.

In describing elements of the present disclosure, the terms “first,” “second,” “A,” “B,” “(a)”, or “(b)”, or the like can be used. These terms are intended to identify the corresponding element(s) from the other element(s), and these terms are not used to define the essence, basis, order, or number of the elements.

For the expression that an element (e.g., layer, film, region, component, section, or the like) is described as “connected,” “coupled,” “attached,” “adhered,” or the like to another element, the element can not only be directly connected, coupled, attached, adhered, or the like to another element, but also be indirectly connected, coupled, attached, adhered, or the like to another element with one or more intervening elements disposed or interposed between the elements, unless otherwise specified.

For the expression that an element (e.g., layer, film, region, component, section, or the like) “contacts,” “overlaps,” or the like with another element, the element can not only directly contact, overlap, or the like with another element, but also indirectly contact, overlap, or the like with another element with one or more intervening elements disposed or interposed between the elements, unless otherwise specified.

The phrase that an element (e.g., layer, film, region, component, section, or the like) is “provided,” “disposed,” “connected,” “coupled,” or the like in, on, with or to another element can be understood as that at least a portion of the element is provided, disposed, connected, coupled, or the like in another element, or that the entirety of the element is provided, disposed, connected, coupled, or the like in another element. The phrase that an element (e.g., layer, film, region, component, section, or the like) “contacts,” “overlaps,” or the like with another element can be understood as that at least a portion of the element contacts, overlaps, or the like with a least a portion of another element, that the entirety of the element contacts, overlaps, or the like with a least a portion of another element, or that at least a portion of the element contacts, overlaps, or the like with the entirety of another element.

The terms such as a “line” or “direction” should not be interpreted only based on a geometrical relationship in which the respective lines or directions are parallel or perpendicular to each other. Such terms can mean a wider range of lines or directions within which the components of the present disclosure can operate functionally. For example, the terms “first direction,” “second direction,” and the like, such as a direction parallel or perpendicular to “x-axis,” “y-axis,” or “z-axis,” should not be interpreted only based on a geometrical relationship in which the respective directions are parallel or perpendicular to each other, and can be meant as directions having wider directivities within the range within which the components of the present disclosure can operate functionally.

The term “at least one” should be understood as including any and all combinations of one or more of the associated listed items. For example, each of the phrases of “at least one of a first item, a second item, or a third item” and “at least one of a first item, a second item, and a third item”, can represent (i) a combination of items provided by one or more of the first item, the second item, and the third item and (ii) only one of the first item, the second item, and the third item.

The expression of a first element, a second elements, “and/or” a third element should be understood to encompass one of the first, second, or third elements, one of the first, second, and third elements, as well as any and all combinations of the first, second and third elements. By way of example, A, B and/or C encompass only A; only B; only C; any of A, B, and C (e.g., A, B, or C); some combinations of A, B, and C (e.g., A and B; A and C; or B and C); and all of A, B, and C. Furthermore, an expression “A/B” can be understood as A and/or B. For example, an expression “A/B” can refer to only A; only B; A or B; or A and B.

In one or more aspects, the terms “between” and “among” can be used interchangeably simply for convenience unless stated otherwise. For example, an expression “between a plurality of elements” can be understood as among a plurality of elements. In another example, an expression “among a plurality of elements” can be understood as between a plurality of elements. In one or more examples, the number of elements can be two. In one or more examples, the number of elements can be more than two. Furthermore, when an element (e.g., layer, film, region, component, sections, or the like) is referred to as being “between” at least two elements, the element can be the only element between the at least two elements, or one or more intervening elements can also be present.

In one or more aspects, the phrases “each other” and “one another” can be used interchangeably simply for convenience unless stated otherwise. For example, an expression “different from each other” can be understood as different from one another. In another example, an expression “different from one another” can be understood as different from each other. In one or more examples, the number of elements involved in the foregoing expression can be two. In one or more examples, the number of elements involved in the foregoing expression can be more than two.

In one or more aspects, the phrases “one or more among” and “one or more of” can be used interchangeably simply for convenience unless stated otherwise.

The term “or” means “inclusive or” rather than “exclusive or.” For example, unless otherwise stated or clear from the context, the expression that “x uses a or b” means any one of natural inclusive permutations. For example, “a or b” can mean “a,” “b,” or “a and b.” For example, “a, b or c” can mean “a,” “b,” “c,” “a and b,” “b and c,” “a and c,” or “a, b and c.”

Features of various aspects of the present disclosure can be partially or entirely coupled to or combined with each other, can be technically associated with each other, and can be operated, linked, or driven together in various ways. Aspects of the present disclosure can be implemented or carried out independently from each other, or can be implemented or carried out together in a co-dependent or related relationship. In one or more aspects, the components of each apparatus according to various aspects of the present disclosure can be operatively coupled and configured.

Unless otherwise defined, the terms (including technical and scientific terms) used herein have the same meaning as commonly understood by one of ordinary skill in the art to which example aspects belong. It should be further understood that terms, such as those defined in commonly used dictionaries, should be interpreted as having a meaning, for example, consistent with their meaning in the context of the relevant art and should not be interpreted in an idealized or overly formal sense, unless expressly defined otherwise herein.

The terms used herein have been selected as being general in the related technical field; however, there can be other terms depending on the development and/or change of technology, convention, preference of technicians, and so on. Therefore, the terms used herein should not be understood as limiting technical ideas, but should be understood as examples of the terms for describing example aspects.

Further, in a specific case, a term can be arbitrarily selected by an applicant, and in this case, the detailed meaning thereof is described herein. Therefore, the terms used herein should be understood based on not only the name of the terms, but also the meaning of the terms and the content hereof.

“X-axis direction,” “Y-axis direction” and “Z-axis direction” should not be construed by a geometric relation only of a mutual vertical relation and can have broader directionality within the range that elements of the present disclosure can act functionally.

In the following description, various example aspects of the present disclosure are described in detail with reference to the accompanying drawings. With respect to reference numerals to elements of each of the drawings, the same elements can be illustrated in other drawings, and like reference numerals can refer to like elements unless stated otherwise. The same or similar elements can be denoted by the same reference numerals even though they are depicted in different drawings. In addition, for convenience of description, a scale, dimension, size, and thickness of each of the elements illustrated in the accompanying drawings can be different from an actual scale, dimension, size, and thickness, and thus, aspects of the present disclosure are not limited to a scale, dimension, size, and thickness illustrated in the drawings.

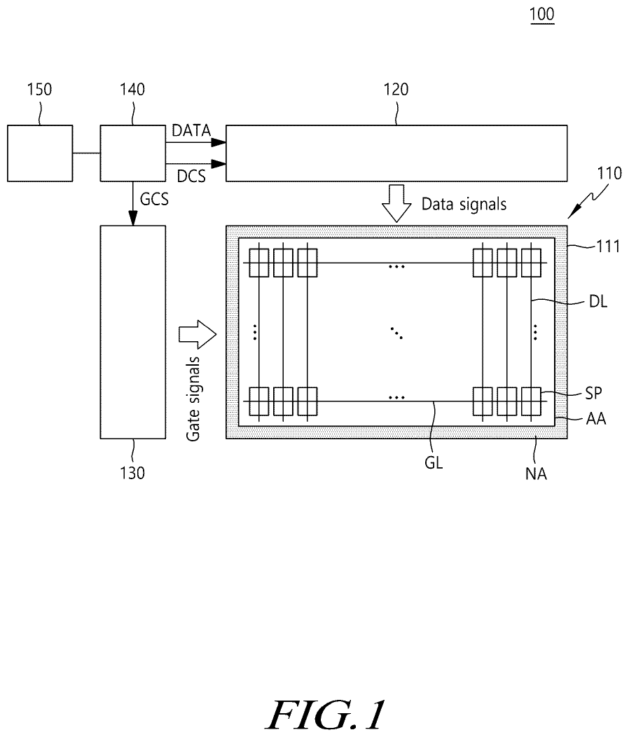

FIG. 1 illustrates an example system configuration of a display apparatus 100 according to aspects of the present disclosure. All components of each display apparatus according to all aspects of the present disclosure are operatively coupled and configured.

Referring to FIG. 1, in one or more aspects, the display apparatus 100 can include a display panel 110 and a display driving circuit, as elements configured to display images. The display driving circuit can be a circuit configured to drive the display panel 110, and include a data driving circuit 120, a gate driving circuit 130, a controller 140, and other circuit components.

The display panel 110 can include a substrate 111 and a plurality of subpixels SP disposed on the substrate 111.

The substrate 111 can include an active area AA allowing an image to be displayed and a non-active area NA located or disposed outside of the active area.

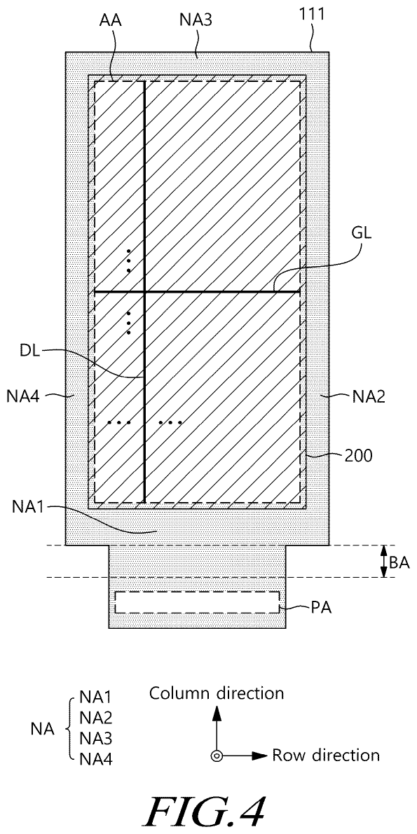

The active area AA can also be referred to as a display area, and a plurality of subpixels SP configured to display images can be disposed at the active area AA. The non-active area NA can also be referred to as a non-display area and can include a pad area PA (see FIG. 4). For example, the pad area PA can be a portion of the non-active area NA disposed in a first direction (e.g., a column direction or a row direction) from the active area AA.

According to aspects of the present disclosure, the display panel 110 can be configured to have very small non-active area NA. Herein, the non-active area NA can also be referred to as “bezel.” For example, the non-active area NA can include a first non-active area located or disposed outside of the active area AA in the first direction, a second non-active area located outside of the active area AA in the second direction, a third non-active area located or disposed outside of the active area AA in a direction opposite to the first direction, and a fourth non-active area located or disposed outside of the active area AA in a direction opposite to the second direction. The first non-active area among the first to fourth non-active areas can include a pad area to which a driving circuit is connected or bonded (or attached). Among the first to fourth non-active areas, the second to fourth non-active areas that do not include a pad area can have a very small size compared to the first non-active area.

In another example, a boundary area can be between the active area AA and the non-active area NA. In this example, the non-active area NA can be bent at a pre-defined (consistent) angle to the active area AA, and thereby, can be disposed under the active area AA. In this implementation, when a user views the display apparatus 100 in front thereof, all or most of the non-active area NA can be not visible to the user. But aspects of the present disclosure are not limited thereto.

Various types of signal lines configured to drive a plurality of subpixels SP can be disposed at the substrate 111 of the display panel 110.

In some aspects, the display apparatus 100 herein can be a liquid crystal display apparatus, or the like, or a self-emission display apparatus in which light is emitted from the display panel 110 itself. In an example where the display apparatus 100 is the self-emission display apparatus, each of the plurality of subpixels SP can include a light emitting element. But aspects of the present disclosure are not limited thereto.

For example, the display apparatus 100 according to aspects of the present disclosure can be an organic light emitting display apparatus in which the light emitting element is implemented using an organic light emitting diode (OLED). In another example, the display apparatus 100 according to aspects of the present disclosure can be an inorganic light emitting display apparatus in which the light emitting element is implemented using an inorganic material-based light emitting diode. In another example, the display apparatus 100 according to aspects of the present disclosure can be a quantum dot display apparatus in which the light emitting element is implemented using quantum dots, which are self-emission semiconductor crystals. But aspects of the present disclosure are not limited thereto.

The structure of each of the plurality of subpixels SP can depend on the type of display apparatus 100. For example, in an example where the display apparatus 100 is a self-emission display apparatus including self-emission subpixels SP, each subpixel SP can include a self-emission light emitting element, one or more transistors, and one or more capacitors.

The various types of signal lines can include, for example, a plurality of data lines DL for carrying data signals (which can be referred to as data voltages or image signals), a plurality of gate lines GL for carrying gate signals (which can be referred to as scan signals), and the like.

In some aspects, the plurality of data lines DL and the plurality of gate lines GL can intersect one another. Each of the plurality of data lines DL can be disposed and be extending in a first direction, and each of the plurality of gate lines GL can be disposed and be extending in a second direction. For example, the first direction can be the column direction, and the second direction can be the row direction. In another example, the first direction can be the row direction, and the second direction can be the column direction. Hereinafter, for convenience of explanation, discussions can be provided based on examples where each of a plurality of data lines DL is disposed in the column direction, and each of a plurality of gate lines GL is disposed in the row direction, but aspects of the present disclosure are not limited thereto.

The data driving circuit 120 can be a circuit configured to drive a plurality of data lines DL and can output data signals to the plurality of data lines DL.

The data driving circuit 120 can receive image data DATA in a digital form from the controller 140, convert the received image data DATA into data signals in an analog form, and output converted data signals to the plurality of data lines DL.

In some aspects, the data driving circuit 120 can be connected to the display panel 110 by a tape-automated-bonding (TAB) method, or connected to a conductive pad such as a bonding pad of the display panel 110 by a chip-on-glass (COG) method or a chip-on-panel (COP) method, or connected to the display panel 110 using a chip-on-film (COF) method. However, aspects of the present disclosure are not limited thereto.

The data driving circuit 120 can be disposed at, and/or electrically connected to, but not limited to, one side or one portion (e.g., an upper portion or a lower portion) of the display panel 110. In some aspects, the data driving circuit 120 can be disposed at, and/or electrically connected to, but not limited to, two sides or portions (e.g., an upper portion and a lower portion) of the display panel 110 or at least two of four sides or portions (e.g., the upper portion, the lower portion, a left portion, and a right portion) of the display panel 110 according to driving schemes, panel design schemes, or the like. The terms left, right, upper, lower in this context are with reference to the typical viewing position.

The data driving circuit 120 can be connected to outside, or a periphery, of the active area AA of the display panel 110, or be disposed in the active area AA of the display panel 110.

The gate driving circuit 130 can be a circuit configured to drive a plurality of gate lines GL and can output gate signals to the plurality of gate lines GL.

The gate driving circuit 130 can receive various types of gate driving control signals GCS, and further, receive a first gate voltage corresponding to a turn-on level voltage and a second gate voltage corresponding to a turn-off level voltage. Thereby, the gate driving circuit 130 can generate gate signals and supply the generated gate signals to the plurality of gate lines GL.

In some aspects, the gate driving circuit 130 in the display apparatus 100 can be embedded into the display panel 110 by a gate-in-panel (GIP) method. In an example where the gate driving circuit 130 is implemented by the gate-in-panel (GIP) method, the gate driving circuit 130 can be disposed on the substrate 111 of the display panel 110 during the manufacturing process of the display panel 110 or display apparatus 100.

In one aspect, the gate driving circuit 130 can be disposed at the non-display area NA of the display panel 110.

In another aspect, the gate driving circuit 130 can be disposed at the active area AA of the display panel 110. In this implementation, for example, the gate driving circuit 130 can be disposed at, and/or electrically connected to, but not limited to, some of a first area (e.g., a left area or a right area) of the active area AA of the display panel 110. In another example, the gate driving circuit 130 can be disposed at, and/or electrically connected to, but not limited to, some of a first area (e.g., a left area or a right area) and some of a second area (e.g., the right area or the left area) of the active area AA of the display panel 110.

Herein, the gate driving circuit 130 embedded in the display panel 110 using the gate-in-panel (GIP) method can also be referred to as a “gate-in-panel circuit.”

The controller 140 can be a device configured to control the data driving circuit 120 and the gate driving circuit 130, and can control driving timing for the plurality of data lines DL and driving timing for the plurality of gate lines GL.

The controller 140 can supply a data control signal DCS to the data driving circuit 120 to control the data driving circuit 120, and supply a gate control signal GCS to the gate driving circuit 130 to control the gate driving circuit 130.

The controller 140 can receive image data input from a host system 150 and supply image data DATA readable by the data driving circuit 120 based on the input image data to the data driving circuit 120.

The controller 140 can be implemented in a separate component from the data driving circuit 120, or integrated with the data driving circuit 120, so that the controller 140 and the data driving circuit 120 can be implemented in a single integrated circuit.

The controller 140 can be a timing controller used in the display technology or a control apparatus/device capable of additionally performing other control functionalities in addition to the function of the timing controller. In one or more aspects, the controller 140 can be one or more other control circuits different from the timing controller, or a circuit or component in the control apparatus/device. The controller 140 can be implemented using various circuits or electronic components such as an integrated circuit (IC), a field programmable gate array (FPGA), an application specific integrated circuit (ASIC), a processor, and/or the like, but aspects of the present disclosure are not limited thereto.

The controller 140 can be mounted on a printed circuit board, a flexible printed circuit, or the like, and can be electrically connected to the data driving circuit 120 and the gate driving circuit 130 through the printed circuit board, the flexible printed circuit, and/or the like.

The controller 140 can transmit signals to, and receive signals from, the data driving circuit 120 via one or more predetermined interfaces. For example, such interfaces can include a low voltage differential signaling (LVDS) interface, an embedded clock point-point interface (EPI), a serial peripheral interface (SPI), and the like. However, aspects of the present disclosure are not limited thereto.

In one or more aspects, to provide a touch sensing function, as well as an image display function, the display apparatus 100 can include a touch sensor, and a touch sensing circuit configured to sense the touch sensor and detect the presence or absence of a touch by an object such as a finger, a pen, or the like, or the location of the touch.

The touch sensing circuit can include a touch driving circuit configured to drive and sense the touch sensor and generate and output touch sensing data, and a touch controller capable of detecting the presence or absence of a touch or the location of the touch by the touch sensing data.

The touch sensor can include a plurality of touch electrodes. The touch sensor can further include a plurality of touch lines to electrically connect the plurality of touch electrodes to the touch driving circuit.

The touch sensor can be disposed outside of the display panel 110 in the form of a touch panel or can be disposed inside of the display panel 110. The touch sensor disposed outside of the display panel 110 can be referred to as an add-on type touch sensor. In the example where the add-on type of touch sensor is disposed in the display apparatus 100, the touch panel and the display panel 110 can be separately manufactured and combined in an assembly process. The add-on type of touch panel can include a touch panel substrate and a plurality of touch electrodes disposed on the touch panel substrate.

In the example where the touch sensor is disposed inside of the display panel 110, the touch sensor can be formed on the substrate along with signal lines and electrodes related to display driving during the manufacturing process of the display panel 110.

The touch driving circuit can supply a touch driving signal to at least one of a plurality of touch electrodes and generate touch sensing data by sensing at least one of the plurality of touch electrodes.

The touch sensing circuit can perform touch sensing by a self-capacitance sensing method or a mutual-capacitance sensing method.

In the example where the touch sensing circuit performs touch sensing by the self-capacitance sensing method, the touch sensing circuit can perform touch sensing based on a capacitance between one or more touch electrode and an object such as a finger, a pen, and/or the like. According to the self-capacitance sensing method, each of a plurality of touch electrodes can serve as both a driving touch electrode and a sensing touch electrode. The touch driving circuit can drive all, or one or more, of a plurality of touch electrodes and sense all, or one or more, of the plurality of touch electrodes.

In the example where the touch sensing circuit performs touch sensing by the mutual-capacitance sensing method, the touch sensing circuit can perform touch sensing based on a capacitance between touch electrodes. According to the mutual-capacitance sensing method, a plurality of touch electrodes can be divided into driving touch electrodes and sensing touch electrodes. The touch driving circuit can drive the driving touch electrodes and sense the sensing touch electrodes.

In some aspects, the touch driving circuit and touch controller included in the touch sensing circuit can be implemented in separate devices or in a single device. In some aspects, the touch driving circuit and the data driving circuit can be implemented in separate devices or in a single device.

The display apparatus 100 can further include a power supply circuit configured to supply various types of power to the display driving circuit and/or the touch sensing circuit.

In some aspects, the display apparatus 100 can be a mobile terminal such as a smart phone, a tablet, or the like, or a monitor, a television (TV), or the like. Such apparatuses can be various types, sizes, and shapes. The display apparatus 100 according to aspects of the present disclosure are not limited thereto, and can include various types, sizes, and shapes configured to display information or images.

In one or more aspects, the display apparatus 100 can further include an electronic apparatus such as a camera (e.g., an image sensor), a sensor capable of detecting an object, and the like. For example, the sensor can be a sensor capable of detecting an object or a human body by receiving light such as infrared light, ultrasonic light, ultraviolet light or the like.

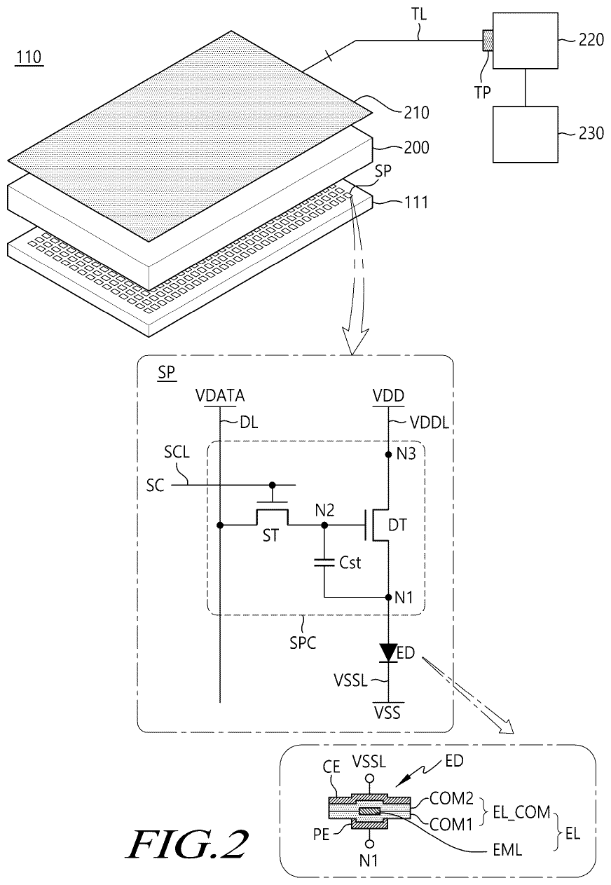

FIG. 2 illustrates a configuration of the display panel 110 according to aspects of the present disclosure.

Referring to FIG. 2, the display panel 110 can include a substrate 111 on which a plurality of subpixels SP are disposed, and an encapsulation layer 200 over the substrate 111. The encapsulation layer 200 can also be referred to as an encapsulation substrate or encapsulation part, or the like.

Referring to FIG. 2, in an example where the display apparatus 100 is a self-emission display apparatus, each of the plurality of subpixels SP disposed on the substrate 111 can include a light emitting element ED and a subpixel circuit SPC for driving the light emitting element ED.

Referring to FIG. 2, the subpixel circuit SPC can include a plurality of transistors and at least one capacitor for driving the light emitting element ED. The subpixel circuit SPC can drive the light emitting element ED by supplying a driving current to the light emitting element ED at a predetermined timing. The light emitting element ED can emit light by being driven by the driving current.

The plurality of transistors can include a driving transistor DT for driving the light emitting element ED and a scan transistor ST configured to be turned on or off according to a scan signal SC.

The driving transistor DT can supply a driving current to the light emitting element ED.

The scan transistor ST can be configured to control an electrical state of a corresponding node in the subpixel circuit SPC or to control the state or operation of the driving transistor DT.

The at least one capacitor can include a storage capacitor Cst to maintain a constant voltage during a frame or a period of the frame.

To drive a subpixel SP, a data signal VDATA, which is an image signal, and a scan signal SC, which is a gate signal, can be applied to the subpixel SP. Further, to drive the subpixel SP, a common pixel driving voltage including a first common driving voltage VDD and a second common driving voltage VSS can be applied to the subpixel SP.

The light emitting element ED can include a pixel electrode PE, an intermediate layer EL, and a common electrode CE. The intermediate layer EL can be disposed between the pixel electrode PE and the common electrode CE.

For example, the pixel electrode PE can be an electrode disposed at each subpixel SP, and the common electrode CE can be an electrode commonly disposed at a plurality of subpixels SP. For example, the pixel electrode PE can be an anode, and the common electrode CE can be a cathode. In another example, the pixel electrode PE can be a cathode, and the common electrode CE can be an anode. Hereinafter, for convenience of explanation, discussions can be provided based on examples where the pixel electrode PE is an anode, and the common electrode CE is a cathode.

In an example where the light emitting element ED is an organic light emitting diode, the intermediate layer EL can include an emission layer EML, a first common intermediate layer COM1 between the pixel electrode PE and the emission layer EML, and a second common intermediate layer COM2 between the emission layer EML and the common electrode CE. A layer including the first common intermediate layer COM1 and the second common intermediate layer COM2 can be referred to as a common intermediate layer EL_COM.

The emission layer EML can be disposed at each subpixel SP, and the common intermediate layer EL_COM can be commonly disposed across a plurality of subpixels SP.

The emission layer EML can be disposed at each light emitting area, and the common intermediate layer EL_COM can be commonly disposed across a plurality of light emitting areas and a non-light emitting area.

For example, the first common intermediate layer COM1 can include a hole injection layer (HIL), a hole transport layer (HTL), and the like. The second common intermediate layer COM2 can include an electron transport layer (ETL), an electron injection layer (EIL), and the like. But aspects of the present disclosure are not limited thereto.

The hole injection layer can inject holes from the pixel electrode PE to the hole transport layer, the hole transport layer can transport holes to the emission layer EML, the electron injection layer can inject electrons from the common electrode CE to the electron transport layer, and the electron transport layer can transport electrons to the emission layer EML. But aspects of the present disclosure are not limited thereto.

For example, the common electrode CE can be electrically connected to a second common driving voltage line VSSL. A second common driving voltage VSS, which is a type of common pixel driving voltage, can be applied to the common electrode CE through the second common driving voltage line VSSL. The pixel electrode PE can be electrically connected directly or indirectly (via another transistor) to a first node N1 of the corresponding driving transistor DT of each subpixel SP. Herein, the second common driving voltage VSS can also be referred to as a “base voltage”, and the second common driving voltage line VSSL can also be referred to as a “low power supply voltage line”, a “low voltage line”, or a “base voltage line”.

Each light emitting element ED can be configured by overlapping of the pixel electrode PE, the emission layer in the intermediate layer EL, and the common electrode CE. Each light emitting element ED can form a corresponding light emitting area. For example, a corresponding light emitting area of each light emitting element ED can include an overlapping area of the pixel electrode PE, the emission layer in the intermediate layer EL, and the common electrode CE.

In some aspects, the light emitting element ED can be an organic light emitting diode (OLED), an inorganic light emitting diode (LED), or a quantum dot light emitting element. For example, in an example where the light emitting element ED is an organic light emitting diode OLED, the intermediate layer EL of the light emitting element ED can be a layer including an organic material. But aspects of the present disclosure are not limited thereto.

The driving transistor DT can be a transistor configured to supply a driving current to the light emitting element ED. The driving transistor DT can be connected between a first common driving voltage line VDDL and the light emitting element ED.

The driving transistor DT can include a first node N1, a second node N2, and a third node N3. The first node N1 can be electrically connected to the light emitting element ED. A data signal VDATA can be applied to the second node N2. The first common driving voltage VDD supplied through the first common driving voltage line VDDL can be applied to the third node N3.

In the driving transistor DT, the second node N2 can be a gate node, the first node N1 can be a source node or a drain node, and the third node N3 can be the drain node or the source node. Hereinafter, for merely convenience of explanation, discussions can be provided based on examples where the first, second, and third nodes (N1, N2, and N3) of the driving transistor DT are source, gate, and drain nodes, respectively. However, aspects of the present disclosure are not limited thereto.

The scan transistor ST in the subpixel circuit SPC illustrated in FIG. 2 can be a switching transistor for allowing a data signal VDATA, which is an image signal, to be supplied to the second node N2, which is the gate node of the driving transistor DT.

The scan transistor ST can be turned on or turned off by a scan signal SC, which is a type of gate signal, applied through a scan line SCL, which is a type of gate line GL, and control an electrical connection between the second node N2 of the driving transistor DT and a data line DL. The drain electrode or source electrode of the scan transistor ST can be electrically connected to the data line DL. The source electrode or drain electrode of the scan transistor ST can be electrically connected to the second node N2 of the driving transistor DT. The gate electrode of the scan transistor ST can be electrically connected to the scan line SCL.

The storage capacitor Cst can be electrically connected between the first node N1 and the second node N2 of the driving transistor DT. The storage capacitor Cst can include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst can be an external capacitor intentionally designed to be located or disposed outside of the driving transistor DT, and therefore, be different from an internal capacitor such as a parasitic capacitor (e.g., a Cgs, a Cgd) that can be formed between the first node N1 and the second node N2 of the driving transistor DT.

Each of the driving transistor DT and the scan transistor ST can be an n-type transistor or a p-type transistor.

The display panel 110 can have a top emission structure or a bottom emission structure.

In an example where the display panel 110 has the top emission structure, at least a portion of the subpixel circuit SPC can overlap with at least a portion of the light emitting element ED in the vertical direction. In this configuration, the area or size of a corresponding light emitting area can be increased, and a corresponding aperture ratio can be increased.

In an example where the display panel 110 has the bottom emission structure, the subpixel circuit SPC can be not overlapping the light emitting element ED in the vertical direction.

As shown in FIG. 2, the subpixel circuit SPC can include two transistors (2T: DT and ST) and one capacitor (1C: Cst) (which can be referred to as a “2TIC structure”), and in some implementations, can further include one or more transistors, or further include one or more capacitors.

For example, the subpixel circuit SPC can have an 8TIC structure including 8 transistors and 1 capacitor. In another example, the subpixel circuit SPC can have an 6T2C structure including 6 transistors and 2 capacitors. In further another example, the subpixel circuit SPC can have a 7T1C structure including 7 transistors and 1 capacitor. Aspects of the present disclosure are not limited to such structures.

The types and number of gate signals supplied to a subpixel SP, and/or the types and number of gate lines connected to the subpixel SP can vary depending on a structure of a corresponding subpixel circuit SPC. Further, the types and number of common pixel driving voltages supplied to a subpixel SP can vary depending on a structure of a corresponding subpixel circuit SPC.

Since circuit elements (e.g., a light emitting element ED such as an organic light emitting diode (OLED) including an organic material) in each subpixel SP are vulnerable to external moisture or oxygen, an encapsulation layer 200 can be disposed at the display panel 110 to prevent the external moisture or oxygen from penetrating into the circuit elements (e.g., the light emitting element ED). The encapsulation layer 200 can be disposed in various shapes or configurations to prevent light emitting elements ED from contacting moisture or oxygen. For example, the encapsulation layer 200 can include two or more layers in which organic and inorganic layers are alternately stacked, but aspects of the present disclosure are not limited thereto.

Referring to FIG. 2, in some aspects, to sense a touch of a user, the display apparatus 100 can include a touch sensor part 210 including a plurality of sensor electrodes, a touch driving circuit 220 configured to sense the plurality of sensor electrodes, and a touch controller 230 configured to determine the presence or absence of a touch or touch coordinates using the sensing result (e.g., touch sensing data) of the touch driving circuit 220.

The touch sensor part 210 can be embedded in the display panel 110. For example, the touch sensor part 210 can be disposed on the encapsulation layer 200 of the display panel 110.

The display panel 110 can include a plurality of touch pads TP to which the touch driving circuit 220 is electrically connected, and a plurality of touch routing lines for electrically connecting the plurality of sensor electrodes included in the touch sensor part 210 to the plurality of touch pads TP to which the touch driving circuit 220 is connected.

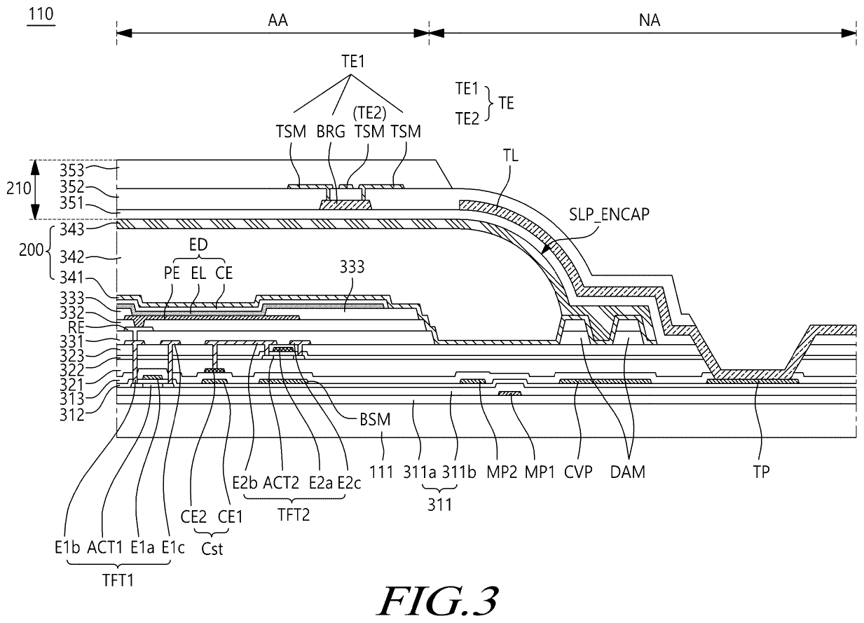

FIG. 3 is a cross-sectional view of the display panel 110 according to aspects of the present disclosure.

Referring to FIG. 3, in some aspects, in terms of stack-up configuration, the display panel 110 can include a transistor forming part, a light emitting element forming part, and an encapsulation part.

The transistor forming part can include a substrate 111, various types of insulating layers (311, 312, 313, 321, 322, and 323) on the substrate 111, various types of transistors (TFT1 and TFT2), a storage capacitor Cst, and various electrodes or signal lines. A transistor forming part can be a transistor part.

The transistors (TFT1 and TFT2) in the transistor forming part can include a first transistor TFT1 and a second transistor TFT2.

The first transistor TFT1 can include a first active layer ACT1, a first electrode E1a, a second electrode E1b, and a third electrode E1c. The first active layer ACT1 can be a first semiconductor layer, but aspects of the present disclosure are not limited thereto. For example, the first active layer ACT1 can be configured with an oxide semiconductor, amorphous silicon, polysilicon, low-temperature polysilicon (LTPS), or the like, but aspects of the present disclosure are not limited thereto. The first transistor TFT1 can be a p-channel transistor or an n-channel transistor, but aspects of the present disclosure are not limited thereto.

The first electrode E1a can be a gate electrode, the second electrode E1b can be a source electrode or a drain electrode, and the third electrode E1c can be the drain electrode or the source electrode. Hereinafter, for convenience of explanation, discussions can be provided based on examples where the first, second, and third electrodes (E1a, E1b, and E1c) are a first gate electrode E1a, a first source electrode E1b, and a first drain electrode E1c, respectively.

The second transistor TFT2 can include a second active layer ACT2, a fourth electrode E2a, a fifth electrode E2b, and a sixth electrode E2c. The second active layer ACT2 can be a second semiconductor layer, but aspects of the present disclosure are not limited thereto. For example, the second active layer ACT2 can be configured with an oxide semiconductor, amorphous silicon, polysilicon, low-temperature polysilicon (LTPS), or the like, but aspects of the present disclosure are not limited thereto. The second transistor TFT2 can be a p-channel transistor or an n-channel transistor, but aspects of the present disclosure are not limited thereto. For example, one of the first transistor TFT1 and the second transistor TFT2 can include an active layer having an oxide semiconductor. In another example, one of the first transistor TFT1 and the second transistor TFT2 can include an active layer having low-temperature polysilicon. In further another example, the first transistor TFT1 and the second transistor TFT2 can include an active layer having an oxide semiconductor. In another example, one or more transistors in a gate driver configured in the gate-in-panel (GIP) type can include active layers having an oxide semiconductor or low temperature polysilicon. In another example, all transistors configured on the substrate and transistors included in a gate driver configured in the gate-in-panel (GIP) type can include active layers having an oxide semiconductor.

The fourth electrode E2a can be a gate electrode, the fifth electrode E2b can be a source electrode or a drain electrode, and the sixth electrode E2c can be the drain electrode or the source electrode. Hereinafter, for convenience of explanation, discussions can be provided based on examples where the fourth, fifth, and sixth electrodes (E2a, E2b, and E2c) are a second gate electrode E2a, a second source electrode E2b, and a second drain electrode E2c, respectively.

The second active layer ACT2 of the second transistor TFT2 can be disposed higher (further) from the substrate 111 than the first active layer ACT1 of the first transistor TFT1.

A first buffer layer 311 can be disposed under the first active layer ACT1 of the first transistor TFT1, and a second buffer layer 321 can be disposed under the second active layer ACT2 of the second transistor TFT2. For example, the first active layer ACT1 of the first transistor TFT1 can be disposed on the first buffer layer 311, and the second active layer ACT2 of the second transistor TFT2 can be disposed on the second buffer layer 321. The second buffer layer 321 can be disposed higher (further from the substrate) than the first buffer layer 311.

The storage capacitor Cst can be disposed in various metal layers in the display panel 110. For example, the storage capacitor Cst can include a first capacitor electrode CE1 and a second capacitor electrode CE2.

The light emitting element forming part can include a plurality of light emitting elements ED disposed on at least one planarization layer (331, and/or 332). Each of the light emitting elements ED can include a pixel electrode PE, an intermediate layer EL, and a common electrode CE. The light emitting element forming part can be the light emitting element part.

The encapsulation part can include an encapsulation layer 200 on the plurality of light emitting elements ED. The encapsulation layer 200 can be formed in a single layer or multiple layers. In addition to the encapsulation layer 200, the encapsulation part can further include at least one dam DAM.

Hereinafter, the stack-up configuration of the display panel 110 according to aspects of the present disclosure will be described in more detail with reference to FIG. 3.

Referring to FIG. 3, the first buffer layer 311 can be disposed on the substrate 111. The first buffer layer 311 can be formed in a single layer or multiple layers. In an example where the first buffer layer 311 has a stack of multiple layers, the first buffer layer 311 can include a multi-buffer layer 311a and an active buffer layer 311b.

The first active layer ACT1 of the first transistor TFT1 can be disposed on the first buffer layer 311. The first active layer ACT1 can include a channel region where a channel is formed, a source connection region on one side of the channel region, and a drain connection region on another side of the channel region.

A first gate insulating layer 312 can be disposed on the first active layer ACT1 of the first transistor TFT1. The first gate electrode E1a of the first transistor TFT1 can be disposed on the first gate insulating layer 312. A first interlayer insulating layer 313 can be disposed on the first gate electrode E1a of the first transistor TFT1.

The second buffer layer 321 can be disposed on the first interlayer insulating layer 313.

The second active layer ACT2 of the second transistor TFT2 can be disposed on the second buffer layer 321. The second active layer ACT2 can include a channel region where a channel is formed, a source connection region on a first side of the channel region, and a drain connection region on a second opposing side of the channel region.

A second gate insulating layer 322 can be disposed on the second active layer ACT2 of the second transistor TFT2. The second gate electrode E2a of the second transistor TFT2 can be disposed on the second gate insulating layer 322. A second interlayer insulating layer 323 can be disposed on the second gate electrode E2a of the second transistor TFT2.

The first source electrode E1b and the first drain electrode E1c of the first transistor TFT1 and the second source electrode E2b and the second drain electrode E2c of the second transistor TFT2 can be disposed on the second interlayer insulating layer 323.

The first source electrode E1b and the first drain electrode E1c of the first transistor TFT1 can be connected to the source connection region and the drain connection region of the first active layer ACT1 respectively through holes formed in the second interlayer insulating layer 323, the second gate insulating layer 322, the second buffer layer 321, the first interlayer insulating layer 313, and the first gate insulating layer 312.

The second source electrode E2b and the second drain electrode E2c of the second transistor TFT2 can be connected to the source connection region and drain connection region of the second active layer ACT2 respectively through holes of the second interlayer insulating layer 323 and the second gate insulating layer 322.

The first source electrode E1b and the first drain electrode E1c of the first transistor TFT1 and the second source electrode E2b and the second drain electrode E2c of the second transistor TFT2 can include a first metal and can be disposed in a first metal layer. The first metal and the first metal layer can be referred to as a first source-drain metal and a first source-drain metal layer, respectively.

Referring to FIG. 3, in one or more aspects, the storage capacitor Cst can be configured with the first capacitor electrode CE1 and the second capacitor electrode CE2. In one or more aspects, the storage capacitor Cst can include three or more capacitor electrodes, or can include two or more capacitors connected in parallel.

Each of the first capacitor electrode CE1 and the second capacitor electrode CE2 can be disposed in various metal layers in or at the display panel 110.

In one or more aspects, the first capacitor electrode CE1 can include the same first gate metal as the first gate electrode E1a of the first transistor TFT1 on the first gate insulating layer 312, and be disposed in or at a first gate metal layer.

In one or more aspects, the second capacitor electrode CE2 can be disposed on the first interlayer insulating layer 313.

The second source electrode E2b of the second transistor TFT2 can be electrically connected to the second capacitor electrode CE2 through holes of the second interlayer insulating layer 323, the second gate insulating layer 322, and the second buffer layer 321.

In one or more aspects, the first transistor TFT1 can be the driving transistor DT of FIG. 2, and the second transistor TFT2 can be the scan transistor ST of FIG. 2.

The transistor forming part can further include various metal layers (e.g., a first metal layer MP1, a second metal layer MP2, and the like). For example, the first metal layer MP1 can be disposed between the multi-buffer layer 311a and the active buffer layer 311b included in the first buffer layer 311. The second metal layer MP2 can include the same first gate metal as the first gate electrode E1a of the first transistor TFT1 and can be disposed in the first gate metal layer. In one or more aspects, the first metal layer MP1 can be a first metal pattern, and the second metal layer MP2 can be a second metal pattern. However, aspects of the present disclosure are not limited thereto.

Each of the first metal layer MP1 and the second metal layer MP2 can be disposed in the active area AA or the non-active area NA.

Referring to FIG. 3, the transistor forming part can further include a shielding layer BSM disposed on the substrate 111, overlapping with the second active layer ACT2 of the second transistor TFT2, and disposed under the second active layer ACT2 of the second transistor TFT2.

For example, the shielding layer BSM can be disposed in the same first gate metal layer as the first gate electrode E1a of the first transistor TFT1. In another example, the shielding layer BSM can be disposed in the same metal layer as the first metal layer MP1 on the first buffer layer 311.

An additional shielding layer BSM can be disposed under the first active layer ACT1 of the first transistor TFT1 and overlapping with the first active layer ACT1 of the first transistor TFT1. In this implementation, the shielding layer BSM can be disposed in the same metal layer as the first metal layer MP1.

Referring to FIG. 3, the transistor forming part can further include a common driving voltage pattern CVP to which a common driving voltage is applied. The common driving voltage applied to the common driving voltage pattern CVP can be a power signal, and for example, can be the first common driving voltage VDD or the second common driving voltage VSS in FIG. 2. The first common driving voltage VDD can be referred to as a high power supply voltage (or a high-potential power signal), and the second common driving voltage VSS can be referred to as a low power supply voltage (or a low-potential power signal) or a base voltage.

The common driving voltage pattern CVP can be disposed in the active area AA or the non-active area NA.

At least one planarization layer can be disposed on the first transistor TFT1 and the second transistor TFT2. FIG. 3 illustrates, for example, two planarization layers (first and second planarization layers 331 and 332) disposed on the first transistor TFT1 and the second transistor TFT2. In one or more aspects, three or more planarization layers can be disposed on the first transistor TFT1 and the second transistor TFT2 according to design requirements. However, aspects of the present disclosure are not limited thereto.

Referring to FIG. 3, the first planarization layer 331 can be disposed on the first source electrode E1b and the first drain electrode E1c of the first transistor TFT1 and the second source electrode E2b and the second drain electrode E2c of the second transistor TFT2. In one or more aspects, the first planarization layer 331 can be disposed and cover both the first transistor TFT1 and the second transistor TFT2.

Referring to FIG. 3, a relay electrode RE (or a connection electrode) can be disposed on the first planarization layer 331. The relay electrode RE can be electrically connected to the first source electrode E1b of the first transistor TFT1 through a hole of the first planarization layer 331. The relay electrode RE can also be called a connection electrode.

The relay electrode RE can be disposed in a second metal layer on the first planarization layer 331, and include a second metal. The second metal and the second metal layer can be referred to as a second source-drain metal and a second source-drain metal layer, respectively.

The second planarization layer 332 can be disposed on the relay electrode RE.

Referring to FIG. 3, the light emitting element forming part can be disposed on the second planarization layer 332. A light emitting element ED can be formed on the second planarization layer 332. The light emitting element ED can include a pixel electrode PE, an intermediate layer EL, and a common electrode CE. The light emitting area of the light emitting element ED can be formed in an area where the pixel electrode PE, the intermediate layer EL, and the common electrode CE overlap and contact each other.

The pixel electrode PE can be disposed on the second planarization layer 332, and a bank 333 can be disposed on the pixel electrode PE. An opening of the bank 333 can expose a portion of the pixel electrode PE to form the light emitting area. For example, the opening of the bank 333 can overlap with a portion of the pixel electrode PE.

The intermediate layer EL of the light emitting element ED can be disposed on a portion of the pixel electrode PE and the bank 333. The common electrode CE can be disposed on the intermediate layer EL.

Referring to FIG. 3, the encapsulation part can be disposed on the light emitting element forming part, and be disposed on the common electrode CE. The encapsulation part can include an encapsulation layer 200 disposed on the common electrode CE.

The encapsulation layer 200 can prevent moisture or oxygen from penetrating into the light emitting element ED. For example, the encapsulation layer 200 can prevent moisture or oxygen from penetrating into an organic material contained in the intermediate layer EL of the light emitting element ED. In one or more aspects, the encapsulation layer 200 can be formed in a single layer or multiple layers, but aspects of the present disclosure are not limited thereto.

Referring to FIG. 3, for example, the encapsulation layer 200 can include a first encapsulation layer 341, a second encapsulation layer 342, and a third encapsulation layer 343. The first encapsulation layer 341 and the third encapsulation layer 343 can include, for example, an inorganic layer, and the second encapsulation layer 342 can include, for example, an organic layer.

In one or more aspects, a touch sensor can be embedded in the display panel 110. In these aspects, the display panel 110 can include a touch sensor part 210 disposed on the encapsulation layer 200.

Referring to FIG. 3, the touch sensor part 210 can include a plurality of touch electrodes TE, and can include touch sensor electrodes TSM and bridge electrodes BRG to form the plurality of touch electrodes TE. The touch sensor electrodes TSM can also be referred to as touch sensor layers TSM. The bridge electrodes BRG can also be referred to as bridge layers BRG.

The touch sensor part 210 can further include one or more insulating layers such as a buffer layer 351 on the encapsulation layer 200, an interlayer insulating layer 352 on the buffer layer 351, and/or a protection layer 353 on the interlayer insulating layer 352. The bridge layers BRG can be disposed between the buffer layer 351 and the interlayer insulating layer 352, and the touch sensor layers TSM can be disposed between the interlayer insulating layer 352 and the protection layer 353.

Each of the plurality of touch electrodes TE can include a touch sensor layer TSM. Each of the plurality of touch electrodes TE can be a mesh-type electrode having a plurality of openings.

The plurality of touch electrodes TE can include one or more first touch electrodes TE1 and one or more second touch electrodes TE2. Touch sensor layers TSM included in a first touch electrode TE1 can be electrically connected through at least one bridge layer BRG.

The buffer layer 351 can be disposed on the encapsulation layer 200, the bridge layers BRG can be disposed on the buffer layer 351, and the interlayer insulating layer 352 can be disposed on the bridge layers BRG.

The touch sensor layers TSM can be disposed on the interlayer insulating layer 352. Respective portions of the touch sensor layers TSM can be connected to corresponding bridge layers BRG through holes formed in the interlayer insulating layer 352.

Referring to FIG. 3, the touch sensor layers TSM and bridge layers BRG can be disposed such that the touch sensor layers TSM and bridge layers BRG can overlap with each other. The touch sensor layers TSM and bridge layers BRG can overlap with the bank 333.

In one or more aspects, a plurality of touch sensor layers TSM can be included in one touch electrode TE, and can be disposed in a mesh pattern and electrically connected to each other. In one or more aspects, one or more of touch sensor layers TSM and the other one or more of touch sensor layers TSM can be electrically connected to each other through one or more bridge layers BRG to form one touch electrode TE.

The sensor protection layer 353 can be disposed and covering the touch sensor layers TSM and the bridge layers BRG.

Referring to FIG. 3, a touch line TL can electrically connect a touch electrode TE to a touch pad TP. The touch line TL can include at least one of a touch sensor layer TSM and a bridge layer BRG.

In an example where the display panel 110 is a display panel in which a touch sensor is embedded, the touch line TL can extend along an outer slope SLP_ENCAP of the encapsulation layer 200 and an upper portion of at least one dam DAM and extend to the touch pad TP located or disposed in the non-active area NA.

FIG. 4 illustrates an example substrate (e.g., the substrate 111 of FIG. 3) of the display panel 110 according to aspects of the present disclosure.

Referring to FIG. 4, in one or more aspects, the substrate 111 of the display panel 110 can include an active area AA allowing an image to be displayed and a non-active area NA in which an image is not displayed.

The non-active area NA can include a first non-active area NA1, a second non-active area NA2, a third non-active area NA3 and a fourth non-active area NA4. But aspects of the present disclosure are not limited thereto. Additional non-active areas or a lesser number of non-active areas can be present.

The first non-active area NA1 can be located or disposed in a first direction from the active area AA. The second non-active area NA2 can be located or disposed in a second direction from the active area AA. The third non-active area NA3 can be located or disposed in a third direction from the active area AA. The fourth non-active area NA4 can be located or disposed in a fourth direction from the active area AA.

For example, the first and third non-active areas (NA1, NA3) can be areas opposite to each other in the column direction. The second and fourth non-active areas (NA2, NA4) can be areas opposite to each other in the row direction. In another example, the first and third non-active areas (NA1, NA3) can be areas opposite to each other in the row direction. The second and fourth non-active areas (NA2, NA4) can be areas opposite to each other in the column direction. Hereinafter, for convenience of explanation, discussions can be provided based on examples where the first and third non-active areas (NA1, NA3) are areas opposite to each other in the column direction, and the second and fourth non-active areas (NA2, NA4) are areas opposite to each other in the row direction.

For example, the column direction can be a direction in which data lines DL are extended, and the row direction can be a direction in which gate lines GL are extended. In another example, the column direction can be a direction in which gate lines GL are extended, and the row direction can be a direction in which data line DL are extended. Hereinafter, for convenience of explanation, discussions can be provided based on examples where the column direction is the direction in which data lines DL are extended, and the row direction is the direction in which gate lines GL are extended. However, aspects of the present disclosure are not limited thereto.

Referring to FIG. 4, the first non-active area NA1 can include a pad area PA. A plurality of pads to which at least one driving circuit or a printed circuit board is electrically connected can be disposed at the pad area PA. In one or more aspects, a plurality of data lines DL, a first common driving voltage line VDDL, and a second common driving voltage line VSSL can be electrically connected to the plurality of pads.

The first non-active area NA1 can further include a bending area BA. In this implementation, the substrate 111 can be a flexible substrate. In one or more aspects, the first non-active area NA1 can be not including a bending area BA.

The display panel 110 can further include a ground line disposed in the non-active area NA of the substrate 111. The ground line can be disposed such that it runs from one point of the pad area PA to another point of the pad area PA via the second non-active area NA2, the third non-active area NA3, and the fourth non-active area NA4.

In one or more aspects, the encapsulation layer 200 disposed in the display panel 110 can have a structure in which at least one inorganic layer and at least one organic layer are stacked, but the aspects of the present disclosure are not limited thereto. In these aspects, an edge of the encapsulation layer 200 can be an edge of an organic layer. The encapsulation layer 200 can extend from the active area AA to a portion of the non-active area NA.

In one or more aspects, to prevent overflow of an organic layer in the encapsulation layer 200, the display panel 110 can further include at least one dam or at least one stopper disposed outside of the organic layer included in the encapsulation layer 200. The at least one dam or the at least one stopper can include an organic layer, but aspects of the present disclosure are not limited thereto.

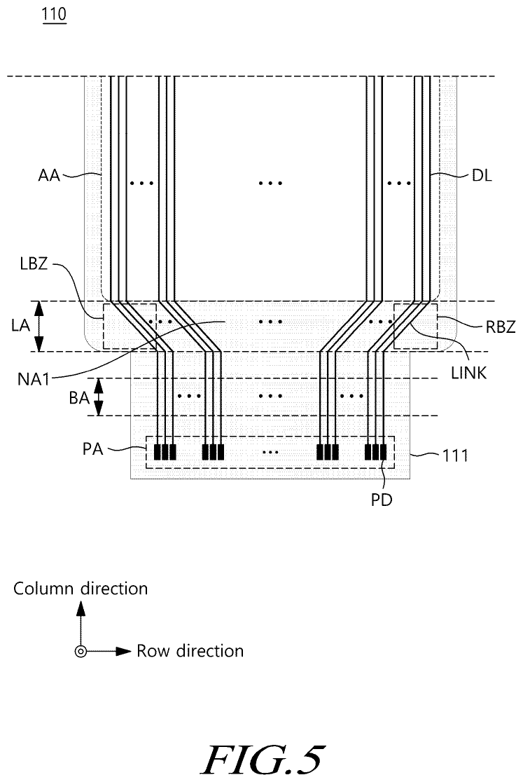

FIG. 5 is an example plan view of the display panel 110 according to aspects of the present disclosure, and illustrates a data link structure configured in the display panel 110.

Referring to FIG. 5, in one or more aspects, the display panel 110 can include a plurality of data lines DL for delivering data voltages VDATA, and a plurality of pads PD disposed at the pad area PA and allowing the data driving circuit 120 to be electrically connected.

In one or more aspects, the display panel 110 can include a data link structure for electrically connecting the plurality of data lines DL to the plurality of pads PD. In one or more aspects, the data link structure can include a plurality of data link lines LINK. The data link line can also be referred to as a link line.

A plurality of data link lines LINK can be disposed in the non-active area NA. For example, the plurality of data link lines LINK can be disposed in the first non-active area NA1 including the pad area PA.

The first non-active area NA1 can further include a link area LA in addition to the pad area PA and the bending area BA.

For example, each of the plurality of data link lines LINK can be disposed across the pad area PA, the bending area BA, and the link area LA. Each of the plurality of data link lines LINK can include a first end (or a first side) electrically connected to a pad PD disposed in the pad area PA, and a second end (or a second side) electrically connected to a data line DL disposed in the active area AA. A portion between both ends (i.e., the first and second ends, or the first and second sides) of each of the plurality of data link lines LINK can be disposed across the bending area BA and the link area LA.

For example, each of the plurality of data link lines LINK can be formed from one line or two or more lines. Each of the plurality of data link lines LINK can be disposed in one metal layer or in two or more metal layers.

The bending area BA can be bent during the manufacturing process of the display panel 110. Accordingly, when a user views the display apparatus 100 in front thereof, the bending area BA and the pad area PA can be not visible to the user.

However, when a user views the display apparatus 100 in front thereof, the link area LA can be recognized as a bezel even when it is covered by a case or cover member. Therefore, in order to implement a narrow bezel, it can be desirable to reduce the area or size of the link area LA.

Referring to FIG. 5, since all of a plurality of data link lines LINK in the link area LA of the first non-active area NA1 are required to be electrically connected to a plurality of data lines DL, the link area LA needs a great area.

For example, when a length of the pad area PA in the second direction (row direction) is less than a length of the active area AA in the second direction (row direction), each of a plurality of data link lines LINK in left and right areas (LBZ and RBZ) of the link area LA is needed to extend at a pre-defined (consistent) angle to the row direction or the column direction and thereafter be electrically connected to a corresponding one of the plurality of data lines DL. This configuration leads the link area LA in the first direction (column direction) to have an increased length and the link area LA to have an increased area.

Accordingly, as shown in FIG. 5, in the example where the display panel 110 has a data link structure in which a plurality of data link lines LINK are disposed in the first non-active area NA1, the link area LA of the first non-active area NA1 can need a great area. In this implementation, when a user views the display apparatus 100 in front thereof, the link area LA can be recognized as a wide bezel.

Therefore, in order to implement a narrow bezel, it is required to provide a data link structure capable of reducing the area of the link area LA. To meet such a requirement, a data link structure capable of implementing a narrow bezel is provided as discussed below.

Hereinafter, a data link structure capable of implementing a narrow bezel according to aspects of the present disclosure will be described.

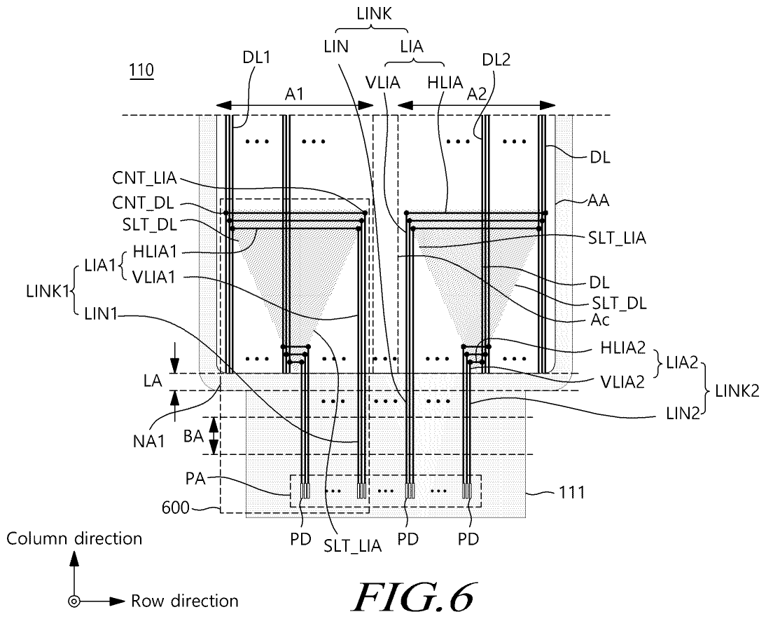

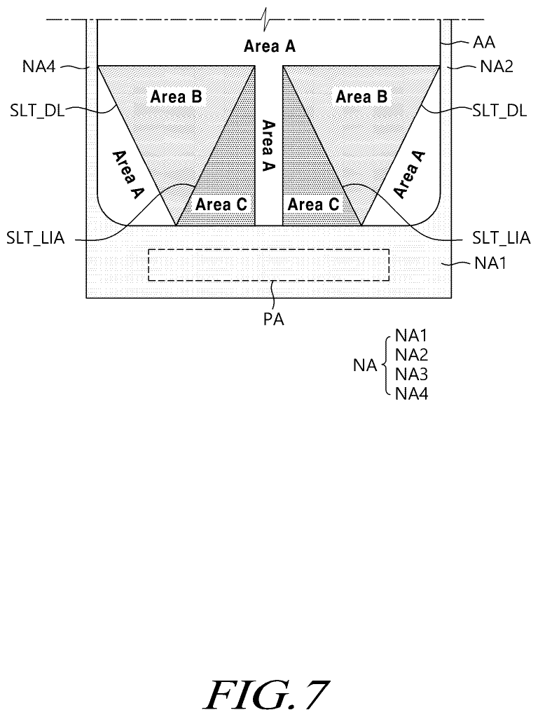

FIG. 6 is an example plan view of the display panel 110 according to aspects of the present disclosure, and illustrates an example data link structure capable of reducing the bezel of the display panel 110 (“bezel reduction data link structure”). FIG. 7 illustrates an example of three areas (A, B, and C areas) in the active area AA by the bezel reduction data link structure of the display panel 110 according to aspects of the present disclosure. In one or more aspects, a data link structure can be a bezel reduction data link structure.

Referring to FIG. 6, the non-active area NA can include a first non-active area NA1 disposed in the column direction from the active area AA. The first non-active area NA1 can include a pad area PA and a link area LA disposed in the column direction from the active area AA.

In one or more aspects, the display panel 110 can include a data link structure capable of reducing the bezel of the display panel 110 and allowing data voltages VDATA to be supplied to a plurality of subpixels SP disposed in the active area AA.

Referring to FIG. 6, in one or more aspects, this bezel reduction data link structure can include a plurality of data link lines LINK configured to electrically connect a plurality of data lines DL to a plurality of pads PD.

The plurality of data lines DL can be disposed in the active area AA, extend in the column direction, and be connected to a plurality of subpixels SP disposed in the active area AA.

The plurality of pads PD can be disposed in the pad area PA included in the first non-active area NA1.

The plurality of data link lines LINK can electrically connect the plurality of pads PD disposed in the pad area PA in the first non-active area NA1 to the plurality of data lines DL disposed at the active area AA.

Referring to FIG. 6, in one or more aspects, each of the plurality of data link lines LINK in the data link structure for the narrow bezel can include a portion LIA disposed at the active area AA.

In the bezel reduction data link structure according to aspects of the present disclosure, the plurality of data link lines LINK and the plurality of data lines DL can be electrically connected to each other in the active area AA. For example, in the bezel reduction data link structure according to aspects of the present disclosure, connection points CNT_DL between the plurality of data link lines LINK and the plurality of data lines DL can be located or disposed in the active area AA.

Accordingly, each of the plurality of data link lines LINK can be not needing to extend at a pre-defined (consistent) angle to the row direction or the column direction in left and right areas of the link area LA, and each of the plurality of data link lines LINK can run the link area LA with a short length in the column direction, and enter the active area AA to be connected to a corresponding data line DL in the active area AA.

As shown in FIG. 6, in the example where the display panel 110 has the bezel reduction data link structure, the length of the link area LA in the column direction can be very short or be zero. Accordingly, the first non-active area NA1 viewed by a user in front of the display panel 110 can become very small.

Referring to FIG. 6, in the bezel reduction data link structure according to aspects of the present disclosure, each of the plurality of data link lines LINK can include a link line LIA of the active area AA (which can be referred to as an active area link line LIA), which can be disposed in the active area AA.

The active area link line LIA can be disposed in the active area AA, and include a horizontal link line HLIA extending in the row direction (i.e., the horizontal direction), and a vertical link line VLIA extending in the column direction (i.e., the vertical direction). The horizontal link line HLIA can be denoted as a first link line, a third link line, and the like, but aspects of the present disclosure are not limited thereto. The vertical link line VLIA can be denoted as a second link line, a fourth link line, and the like, but aspects of the present disclosure are not limited thereto.

Each vertical link line VLIA can electrically connect a corresponding pad PD to a corresponding horizontal link line HLIA. Each horizontal link line HLIA can electrically connect a corresponding vertical link line VLIA to a corresponding data line DL.

The horizontal link line HLIA and the vertical link line VLIA can be electrically connected to each other at a connection point CNT_LIA. The horizontal link line HLIA and the data line DL can be electrically connected to each other at a connection point CNT_DL.

Referring to FIG. 6, each of the plurality of data link lines LINK can further include a link line LIN of the non-active area NA (which can be referred to as a non-active area link line LIN), which can be disposed in the first non-active area NA1 of the non-active area NA.

For example, the non-active area link line LIN and the vertical link line VLIA can be formed in a single line. In another example, the non-active area link line LIN can be electrically connected to the vertical link line VLIA, and be disposed in a different metal layer from a metal layer in which the vertical link line VLIA is disposed. In further another example, the non-active area link line LIN can include a line electrically connected to the vertical link line VLIA and disposed in a different metal layer from a metal layer in which the vertical link line VLIA is disposed.

In the example where the display panel 110 has the bezel reduction data link structure as shown in FIG. 6, a horizontal link line HLIA included in each of a plurality of data link lines LINK can run parallel to a plurality of gate lines GL disposed in the active area AA and extending in the row direction (the horizontal direction).

Further, in the example where the display panel 110 has the bezel reduction data link structure as shown in FIG. 6, the horizontal link line HLIA included in each of the plurality of data link lines LINK can overlap with at least one gate line GL in the vertical direction.

Referring to FIG. 6, among a plurality of vertical link lines VLIA, a vertical link line VLIA electrically connected to a data line DL located or disposed closer to the center of the active area AA can have a relatively short length. Among the plurality of vertical link lines VLIA, a vertical link line VLIA electrically connected to a data line DL further away from the center of the active area AA can have a length greater than a vertical link line VLIA electrically connected to a data line DL located or disposed close to the center of the active area AA. Among the plurality of vertical link lines VLIA, a vertical link line VLIA electrically connected to a data line DL located or disposed closer to the center of the active area AA can have a length shorter than a vertical link line VLIA electrically connected to a data line DL further away from the center of the active area AA. But aspects of the present disclosure are not limited thereto.

Among a plurality of horizontal link lines HLIA, a horizontal link line HLIA electrically connected to a data line DL located or disposed closer to the center of the active area AA can have a relatively short length. Among the plurality of horizontal link lines HLIA, a horizontal link line HLIA electrically connected to a data line DL further away from the center of the active area AA can have a length greater than a horizontal link line HLIA electrically connected to a data line DL located or disposed close to the center of the active area AA. Among the plurality of horizontal link lines HLIA, a horizontal link line HLIA electrically connected to a data line DL located or disposed closer to the center of the active area AA can have a length shorter than a horizontal link line HLIA electrically connected to a data line DL further away from the center of the active area AA. But aspects of the present disclosure are not limited thereto.

Among the plurality of horizontal link lines HLIA, a horizontal link line HLIA closer to the pad area PA can have a relatively short length. Among the plurality of horizontal link lines HLIA, a horizontal link line HLIA further away from the pad area PA can have a relatively great length. Among the plurality of horizontal link lines HLIA, a horizontal link line HLIA closer to the pad area PA can have a length shorter than a horizontal link line HLIA further away from the pad area PA. But aspects of the present disclosure are not limited thereto.

A first data link line LINK1 can include an active area link line LIA1 and a non-active area link line LIN1. The active area link line LIA1 included in the first data link line LINK1 can include a first link line HLIA1, which is a horizontal link line, and a second link line VLIA1, which is a vertical link line.

A second data link line LINK2 can include an active area link line LIA2 and a non-active area link line LIN2. The active area link line LIA2 included in the second data link line LINK2 can include a third link line HLIA2, which is a horizontal link line, and a fourth link line VLIA2, which is a vertical link line.

Among the second link line VLIA1 and the fourth link line VLIA2, which are the vertical link lines, the second link line VLIA1 electrically connected to a first data line DL1 located or disposed more outwardly among the first data line DL1 and a second data line DL2 can have a greater length than the fourth link line VLIA2.

Further, among the first link line HLIA1 and the third link line HLIA2, which are the horizontal link lines, the first link line HLIA1 electrically connected to the first data line DL1 located or disposed more outwardly among the first data line DL1 and the second data line DL2 can have a greater length than the third link line HLIA2.

Since the first link line HLIA1 has a greater length than the third link line HLIA2, a first size of an area where the first link line HLIA1 overlaps with at least one gate line GL can be greater than a second size of an area where the third link line HLIA2 overlaps with at least one gate line GL.

As shown in FIG. 6, points CNT_DL where data lines DL and horizontal link lines HLIA are connected can form two first slant lines SLT_DL. Further, points CNT_LIA where vertical link lines VLIA and horizontal link lines HLIA are connected can form two second slant lines SLT_LIA when connected by imaginary lines.

As shown in FIG. 6, two triangles (shown as 2 shaded triangles in FIG. 6) can be formed by the two first slant lines SLT_DL and the two second slant lines SLT_LIA. In each of the two triangles, one of three sides can be a horizontal side parallel to the horizontal link lines HLIA, and a vertex facing this horizontal side can be located or disposed in a boundary between the active area AA and the first non-active area NA or be located or disposed at a place near the boundary.

Referring to FIG. 6, the active area AA can include a central area Ac, a first area A1 on a first side of the central area Ac, and a second area A2 on a second opposing side of the central area Ac.

Data lines DL disposed in the first area A1 and the second area A2 can be connected to non-active area link lines LIN through active area link lines LIA.

In an embodiment, at least one data line DL disposed in the central area Ac can be directly connected to a corresponding non-active area link line LIN without an active area link line LIA.

In the example where the display panel 110 has the bezel reduction data link structure as shown in FIG. 6, respective horizontal link lines HLIA in a plurality of data link lines LINK can be parallel to a plurality of gate lines GL disposed in the active area AA and extending in the row direction (the horizontal direction), and respective horizontal link lines HLIA included in the plurality of data link lines LINK can overlap with at least one gate line GL in the vertical direction.

Referring to FIG. 7, according to the bezel reduction data link structure described above, the active area AA can include three areas (A, B, and C).

A first area (Area A) can be an area in which the bezel reduction data link structure is not configured. A second area (Area B) and a third area (Area C) can be areas where the bezel reduction data link structure is configured. The second area (Area B) can be an area where horizontal link lines HLIA are disposed, and the third area (Area C) can be an area where vertical link lines VLIA are disposed.

Among the first to fourth non-active areas (NA1 to NA4) included in the non-active area NA, the first non-active area NA1 including the pad area PA can contact with one side of each third area (Area C).

The second area (Area B) can have an inverted triangle shape or an isosceles triangle shape, but aspects of the present disclosure are not limited thereto. The active area AA can include two second areas (Area B). The two second areas (Area B) can be respectively located or disposed on both sides of the first area (Area A) located or disposed in the central area of the active area AA.

The third area (Area C) can have a right triangle shape, but aspects of the present disclosure are not limited thereto. The active area AA can include two third areas (Area C). The two third areas (Area C) can be respectively located or disposed on both sides of the first area (Area A) located in the central area of the active area AA. The right triangle shape can also be called a right-angled triangle shape, an orthogonal triangle shape, or a rectangular triangle shape.

The first area (Area A) can be located on (or at the top of) the two second areas (Area B), also be located or disposed between the two third areas (Area C), and also be located outside of the two second areas (Area B). The first area (Area A) located or disposed between the two third areas (Area C) can correspond to the central area Ac of FIG. 6.

Referring to FIGS. 6 and 7, the first area (Area A), the second area (Area B) and the third area (Area C) can be differently arranged and/or can each have a different shape from those shown in FIGS. 6 and 7 in other embodiments of the present disclosure. For example, FIG. 7 shows adjacent third areas (Area C) having a portion of the first area (Area A) that is interposed therebetween so as to overlap the central area Ac (see FIG. 6). However, the active area AA need not have the portion of the first area (Area A) be overlapped or coinciding with the central area Ac. Rather, adjacent third areas (Area C) can be combined to form a single third area (Area C) in a form of an isosceles triangle.

Also, referring to FIGS. 6 and 7, a shape of the second area (Area B) need not be an isosceles triangle as shown, but can be a polygon, such as a trapezoid, a parallelogram or others. When the second area (Area B) is a parallelogram, the length of the first link lines HLIA1 or the second link lines HLIA2 can be the same.

Referring to FIGS. 6 and 7, a boundary between the first area (Area A) and each of the two second areas (Area B) can correspond to points CNT_DL where horizontal link lines HLIA and data lines DL are connected, and form a first slant line SLT_DL.

A boundary between each second area (Area B) and each third area (Area C) can correspond to points CNT_LIA where vertical link lines VLIA and horizontal link lines HLIA are connected, and form a second slant line SLT_LIA.

As shown in FIG. 7, the first slant line SLT_DL and the second slant line SLT_LIA are slanted in different directions. But aspects of the present disclosure are not limited thereto. For example, the first slant line SLT_DL and the second slant line SLT_LIA can be parallel, or be slanted in the same direction.

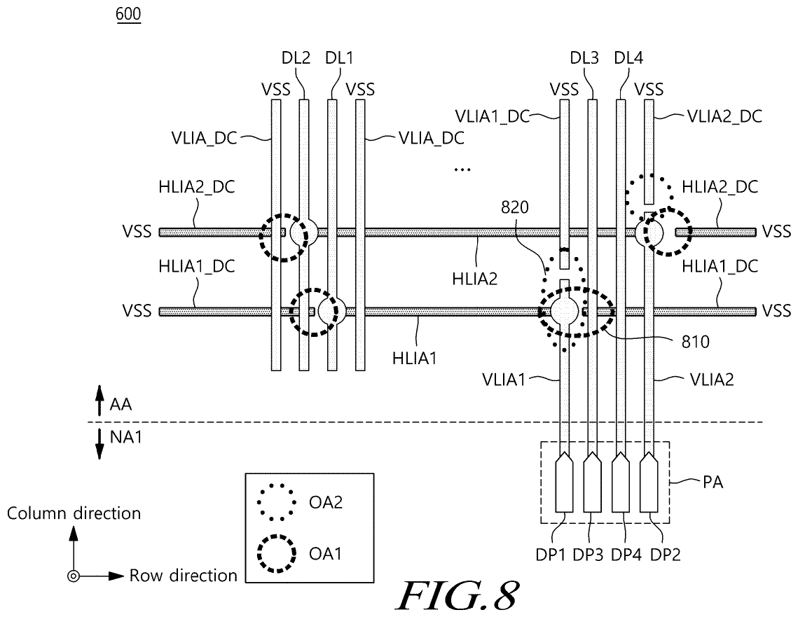

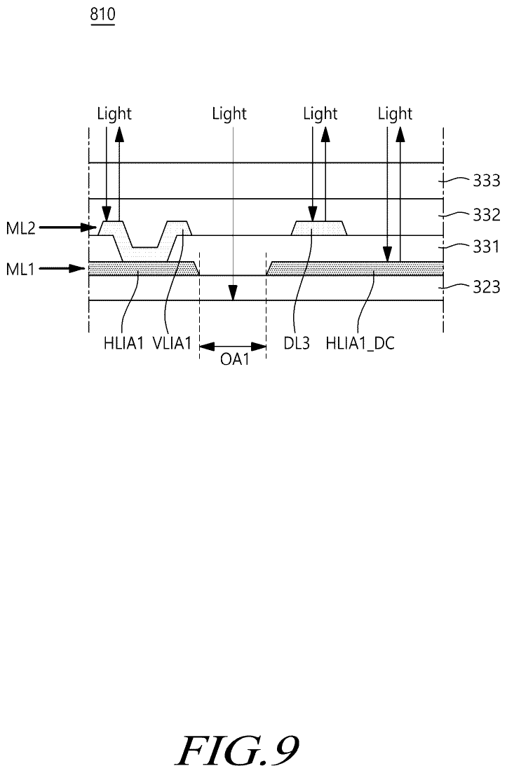

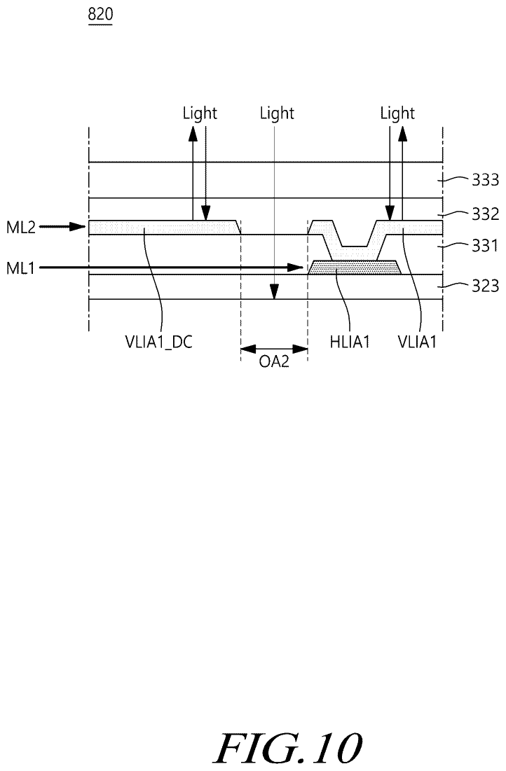

FIG. 8 illustrates an area of the display panel 110 with a data link structure (e.g., the bezel reduction data link structure discussed above) according to aspects of the present disclosure. FIG. 8 is an enlarged plan view for an area 600 of FIG. 6 in which the data link structure (i.e., the bezel reduction data link structure) is configured. FIG. 9 is an example cross-sectional view illustrating a first open area OA1 of a first metal layer ML1 of the display panel 110 according to aspects of the present disclosure. FIG. 9 is across-sectional view of an area 810 including the first open area OA1 of the first metal layer ML1 of FIG. 8. FIG. 10 is an example cross-sectional view illustrating a second open area OA2 of a second metal layer ML2 of the display panel 110 according to aspects of the present disclosure. Discussions that follow will be provided with reference to FIG. 6, as well as FIGS. 8, 9 and 10.

Referring to FIG. 8, the first non-active area NA1 can include the pad area PA where a plurality of data pads (DP1, DP2, DP3, and/or DP4) are disposed. The plurality of data pads (DP1, DP2, DP3, and/or DP4) can include a first data pad DP1, a second data pad DP2, a third data pad DP3, and a fourth data pad DP4. But aspects of the present disclosure are not limited thereto, and additional data pads can be used.

A plurality of data lines DL can be disposed in or at the active area AA, and include a first data line DL1, a second data line DL2, a third data line DL3, and a fourth data line DL4. Each of the first data line DL1, the second data line DL2, the third data line DL3, and the fourth data line DL4 can be disposed in the active area AA, and extend in the column direction. A corresponding data voltage can be applied to each of the first data line DL1, the second data line DL2, the third data line DL3, and the fourth data line DL4.

Referring to FIGS. 8 and 6, a data link structure (e.g., the bezel reduction data link structure discussed above) can be configured in a portion of the active area AA adjacent to the first non-active area NA1. Thus, the bezel reduction data link structure discussed with reference to FIG. 6 can be configured for the data link structure of FIG. 8.

Referring to FIGS. 8 and 6, the data link structure can include active area link lines LIA. The active area link lines LIA can include horizontal link lines HLIA and vertical link lines VLIA.

Each of the horizontal link lines HLIA can be disposed in the active area AA. All or at least part of each of the vertical link lines VLIA can be disposed in the active area AA.

Referring to FIG. 8, the horizontal link lines HLIA can include a first link line HLIA1 and a third link line HLIA2. The first link line HLIA1 can be electrically connected to the first data line DL1. The first link line HLIA1 can be disposed in the active area AA. The first link line HLIA1 can extend in the row direction. The first link line HLIA1 can be disposed in a first metal layer ML1.

The third link line HLIA2 can be electrically connected to the second data line DL2. The third link line HLIA2 can be placed in the active area AA. The third link line HLIA2 can extend in the row direction. The third link line HLIA2 can be disposed in the first metal layer ML1.

Referring to FIG. 8, the vertical link lines VLIA can include a second link line VLIA1 and a fourth link line VLIA2. The second link line VLIA1 can electrically connect the first link line HLIA1 to the first data pad DP1. The second link line VLIA1 can extend in the column direction. The second link line VLIA1 can be disposed in a second metal layer ML2 different from the first metal layer ML1. All or at least part of the second link line VLIA1 can be disposed in the active area AA.

The fourth link line VLIA2 can electrically connect the third link line HLIA2 to the second data pad DP2. The fourth link line VLIA2 can extend in the column direction. The fourth link line VLIA2 can be located or disposed in the second metal layer ML2 different from the first metal layer ML1. All or at least part of the fourth link line VLIA2 can be disposed in or at the active area AA.

Referring to FIG. 8, in one or more aspects, the display panel 110 can further include a first metal pattern HLIA1_DC spaced apart from the first link line HLIA1 and extending in the row direction. The first metal pattern HLIA1_DC can be disposed in the first metal layer ML1. The first metal pattern HLIA1_DC and the first link line HLIA1 can be parallel to each other or may be disposed in same row direction.

In one or more aspects, the display panel 110 can further include a second metal pattern VLIA1_DC spaced apart from the second link line VLIA1 and extending in the column direction. The second metal pattern VLIA1_DC can be located or disposed in the second metal layer ML2.

In one or more aspects, the display panel 110 can further include a third metal pattern HLIA2_DC spaced apart from the third link line HLIA2 and extending in the row direction. The third metal pattern HLIA2_DC can be disposed in the first metal layer ML1.

In one or more aspects, the display panel 110 can further include a fourth metal pattern VLIA2_DC spaced apart from the fourth link line VLIA2 and extending in the column direction. The fourth metal pattern VLIA2_DC can be disposed in the second metal layer ML2.

If the first and third metal patterns (HLIA1_DC and HLIA2_DC) are not disposed in areas where the first and third link lines (HLIA1 and HLIA2) are not disposed, light reflection characteristics in areas where the first and third link lines (HLIA1 and HLIA2) are disposed may be different from light reflection characteristics in areas where the first and third link lines (HLIA1 and HLIA2) are not disposed. Here, the light reflection characteristics may also be referred to as the degree of light reflection, amount of light reflection, or light reflectance. For example, the degree of light reflection in areas where the first and third link lines (HLIA1 and HLIA2) are disposed may be greater than the degree of light reflection in areas where the first and third link lines (HLIA1 and HLIA2) are not disposed. Due to such a configuration, respective light reflection characteristics in each location inside of the display panel 110 can become significantly different, this leading to display artifacts such as image abnormalities, luminance disparities, color differences, and the like. For example, the deviation of the light reflection characteristics between the area where the first and third link lines (HLIA1 and HLIA2) are not disposed and the area where the first and third link lines (HLIA1 and HLIA2) are disposed may vary greatly, and thus, display artifacts such as image abnormalities, luminance disparities, color differences, and the like may occur. The light can include at least a part of light (or internal light) emitted from one or more light emitting elements ED and an external light introduced into the display panel 110 from the outside.

If the second and fourth metal patterns (VLIA1_DC and VLIA2_DC) are not disposed in areas where the second and fourth link lines (VLIA1 and VLIA2) are not disposed, light reflection characteristics in areas where the second and fourth link lines (VLIA1 and VLIA2) are disposed may be different from light reflection characteristics in areas where the second and fourth link lines (VLIA1 and VLIA2) are not disposed. Here, the light reflection characteristics may also be referred to as the degree of light reflection, amount of light reflection, or light reflectance. For example, the degree of light reflection in areas where the second and fourth link lines (VLIA1 and VLIA2) are disposed may be greater than the degree of light reflection in areas where the second and fourth link lines (VLIA1 and VLIA2) are not disposed. Due to such a configuration, respective characteristics of reflecting light in each location inside of the display panel 110 can become significantly different, this leading to display artifacts such as image abnormalities, luminance disparities, color differences, and the like. For example, the deviation of the light reflection characteristics between the area where the first and third link lines (HLIA1 and HLIA2) are not disposed and the area where the first and third link lines (HLIA1 and HLIA2) are disposed may vary greatly, and thus, display artifacts such as image abnormalities, luminance disparities, color differences, and the like may occur.

By placing the first and third metal patterns (HLIA1_DC and HLIA2_DC) in areas where the first and third link lines (HLIA1 and HLIA2) are not disposed, the difference between light reflection characteristics in areas where the first and third link lines (HLIA1 and HLIA2) are disposed and light reflection characteristics in areas where the first and third link lines (HLIA1 and HLIA2) are not disposed may be reduced. By placing the second and fourth metal patterns (VLIA1_DC and VLIA2_DC) in areas where the second and fourth link lines (VLIA1 and VLIA2) are not disposed, the difference between light reflection characteristics in areas where the second and fourth link lines (VLIA1 and VLIA2) are disposed and light reflection characteristics in areas where the second and fourth link lines (VLIA1 and VLIA2) are not disposed may be reduced. Accordingly, display artifacts due to presence or absence of in one or more metal layers can be reduced by the first and third metal patterns (HLIA1_DC and HLIA2_DC) and the second and fourth metal patterns (VLIA1_DC and VLIA2_DC).

In one or more aspects, the display panel 110 can further include a metal pattern VLIA_DC adjacent to the first data line DL1 and extending in the column direction, and a metal pattern VLIA_DC adjacent to the second data line DL2 and extending in the column direction.

The first and third metal patterns (HLIA1_DC and HLIA2_DC) and the second and fourth metal patterns (VLIA1_DC and VLIA2_DC) can serve as a line to which the low power supply voltage VSS, which is the second common driving voltage, is applied.

Each of the first and third metal patterns (HLIA1_DC and HLIA2_DC) may extend in the row direction, and each of the second and fourth metal patterns (VLIA1_DC and VLIA2_DC) may extend in the column direction. Accordingly, the first and third metal patterns (HLIA1_DC and HLIA2_DC) and the second and fourth metal patterns (VLIA1_DC and VLIA2_DC) can be configured in a mesh pattern and intersecting each other. By applying this configuration, an area through which the low power supply voltage VSS, which is the second common driving voltage, is supplied can be significantly increased by the first and third metal patterns (HLIA1_DC and HLIA2_DC) and the second and fourth metal patterns (VLIA1_DC and VLIA2_DC). Thereby, the transmission characteristics of the low power supply voltage VSS can also be significantly improved.

In addition, the length and area of paths through which data voltages are transmitted can be reduced, because the first link line HLIA1 and the first metal pattern HLIA1_DC extending in the same direction are spaced apart from each other, and the second link line VLIA1 and the second metal pattern VLIA1_DC extending in the same direction are spaced apart from each other. By applying this configuration, parasitic capacitance related to the first data line DL1 can be reduced.

In addition, the length and area of paths through which data voltages are transmitted can be reduced, because the third link line HLIA2 and the third metal pattern HLIA2_DC extending in the same direction are spaced apart from each other, and the fourth link line VLIA2 and the fourth metal pattern VLIA2_DC extending in the same direction are spaced apart from each other. By applying this configuration, parasitic capacitance related to the second data line DL2 can be reduced.

The reduction of parasitic capacitance related to the first and second data lines DL1 and DL2 can help improve image quality.

Referring to FIGS. 8 and 9, a difference in reflected light resulting from the reflection of light inside of the display panel 110 can occur between a first open area OA1 where the first link line HLIA1 and the first metal pattern HLIA1_DC are disconnected and an area where the first link line HLIA1 and the first metal pattern HLIA1_DC are disposed. The light can include at least a part of light (or internal light) emitted from one or more light emitting elements ED and external light introduced into the display panel 110 from the outside. The reflected light can be light reflected among light (or internal light) and external light.

Referring to FIGS. 8 and 9, the first link line HLIA1 and the first metal pattern HLIA1_DC can be disposed in the first metal layer ML1 and be arranged in the same row. Accordingly, the first open area OA1 where the first link line HLIA1 and the first metal pattern HLIA1_DC are disconnected can also be referred to as the first open area OA1 of the first metal layer ML1.

Referring to FIGS. 8 and 10, a difference in reflected light resulting from the reflection of light inside of the display panel 110 can occur between a second open area OA2 where the second link line VLIA1 and the second metal pattern VLIA1_DC are disconnected and an area where the second link line VLIA1 and the second metal pattern VLIA1_DC are disposed. The light can include at least a part of light (or internal light) emitted from one or more light emitting elements ED and external light introduced into the display panel 110 from the outside. The reflected light can be light reflected among light (or internal light) and external light.

Referring to FIGS. 8 and 10, the second link line VLIA1 and the second metal pattern VLIA1_DC can be disposed in the second metal layer ML2 and be arranged in the same column. Accordingly, the second open area OA2 where the second link line VLIA1 and the second metal pattern VLIA1_DC are disconnected can also be referred to as the second open area OA2 of the second metal layer ML2.

Referring to FIG. 7, the first open area OA1 of the first metal layer ML1 can be present at a boundary of the first area (Area A) and the second area (Area B) among the three areas (A, B, C) in the active area AA by the bezel reduction data link structure. Accordingly, a plurality of first open areas OA1 can be located along the first slant line SLT_DL.

In addition, the first open area OA1 of the first metal layer ML1 and the second open area OA2 of the second metal layer ML2 can be present at a boundary of the second area (Area B) and the third area (Area C) among the three areas (A, B, C) in the active area AA by the bezel reduction data link structure. Accordingly, a plurality of the first areas OA1 and/or a plurality of second open areas OA2 can be located long the second slant line SLT_LIA.

Referring to FIGS. 9 and 10, the first link line HLIA1 and the first metal pattern HLIA1_DC can be disposed on a second interlayer insulating layer 323 (e.g., the second interlayer insulating layer 323 of FIG. 3) and be spaced apart from each other.

A first planarization layer 331 (e.g., the first planarization layer 331 of FIG. 3) can be disposed on the first link line HLIA1 and the first metal pattern HLIA1_DC.

Referring to FIGS. 9 and 10, the second link line VLIA1, the second metal pattern VLIA1_DC, and one or more other vertical lines (e.g., a data line DL3, and the like) can be disposed on the first planarization layer 331.

Referring to FIGS. 9 and 10, the second link line VLIA1 can be connected to the first link line HLIA1 through a hole formed in the first planarization layer 331.

Referring to FIGS. 9 and 10, a second planarization layer 332 (e.g., the second planarization layer 332 of FIG. 3) can be disposed on the second link line VLIA1, the second metal pattern VLIA1_DC, and one or more other vertical lines (e.g., a data line DL3, and the like). A bank 333 (e.g., the bank 333 of FIG. 3) can be disposed on the second planarization layer 332.

Referring to FIG. 9, the first link line HLIA1 and the first metal pattern HLIA1_DC can be disposed in the first metal layer ML1. Reflected light reflected by metal can be reduced in the first open area OA1 between the first link line HLIA1 and the first metal pattern HLIA1_DC. Due to such a configuration, a difference in reflected light between the first open area OA1 and an area around the first open area OA1 can occur.

Referring to FIG. 10, the second link line VLIA1 and the second metal pattern VLIA1_DC can be disposed in the second metal layer ML2. Reflected light reflected by metal can be reduced in the second open area OA2 between the second link line VLIA1 and the second metal pattern VLIA1_DC. Due to such a configuration, a difference in reflected light between the second open area OA2 and an area around the second open area OA2 can occur.

Differences in reflected light resulting from the reflection of light by the first open area OA1 in the first metal layer ML1 and the second open area OA2 in the second metal layer ML2 can cause display artifacts, such as image abnormalities, luminance disparities, color differences, and the like. The light can include at least a part of light (or internal light) emitted from one or more light emitting elements ED and external light introduced into the display panel 110 from the outside. The reflected light can be light reflected among light (or internal light) and external light.

In a situation where the first open area OA1 in the first metal layer ML1 and the second open area OA2 in the second metal layer ML2 are not applied or present, lengths of active area link lines LIA and data lines DL connected to the active area link lines LIA become greater because the first open area OA1 in the first metal layer ML1 and the second open area OA2 in the second metal layer ML2 are removed. Thereby, parasitic capacitance caused by the active area link lines LIA and the data lines DL can increase, and degradation of image quality can be caused such as display artifacts. In addition, in a situation where the first open area OA1 in the first metal layer ML1 and the second open area OA2 in the second metal layer ML2 are not applied or present, the first metal pattern HLIA1_DC and the second metal pattern VLIA1_DC cannot be used as power lines (low power supply voltage lines VSSL) for transmitting the low power supply voltage VSS because the first open area OA1 in the first metal layer ML1 and the second open area OA2 in the second metal layer ML2 are removed, and this can cause a large voltage drop in the low power supply voltage VSS. Thereby, taking account of the voltage drop of the low power supply voltage VSS, an associated power supply circuit can be required to output an increased low power supply voltage VSS. For example, this situation, in which the first open area OA1 in the first metal layer ML1 and the second open area OA2 in the second metal layer ML2 are not applied, can cause rising of the low power supply voltage VSS to increase.

When the first and third metal patterns (HLIA1_DC, HLIA2_DC) and the second and fourth metal patterns (VLIA1_DC, VLIA2_DC) are disposed, image abnormalities due to presence or absence of metal layers can be reduced and transmission characteristics of low-potential power voltage can be improved. However, when the first and third metal patterns (HLIA1_DC, HLIA2_DC) and the second and fourth metal patterns (VLIA1_DC, VLIA2_DC) are disposed, the first open area OA1 in the first metal layer ML1 and the second open area OA2 in the second metal layer ML2 exist, and a difference of reflected light occurs due to the first open area OA1 and the second open area OA2. Accordingly, it is desirable to reduce the difference in reflected light caused by first open area OA1 in the first metal layer ML1 and the second open area OA2 in the second metal layer ML2.

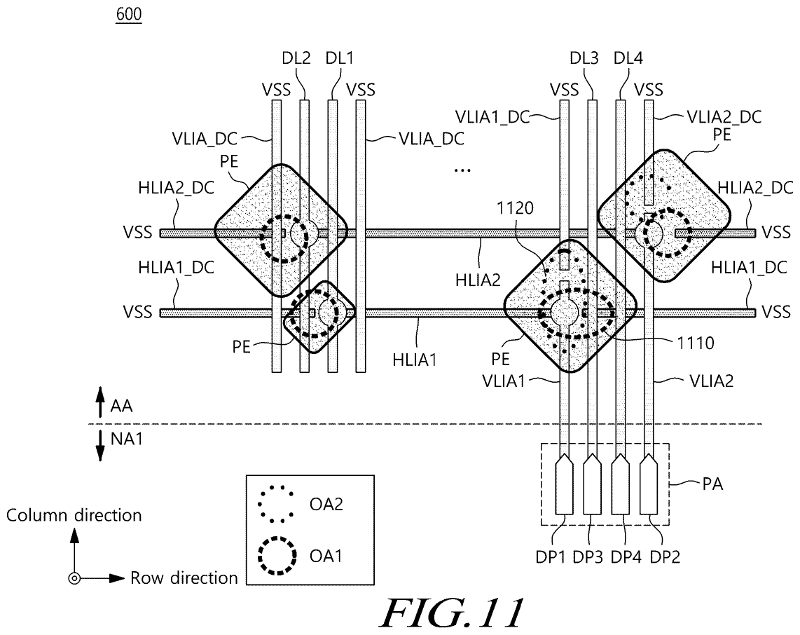

Accordingly, in one or more aspects, the display apparatus 100 and the display panel 110 can have a light reflection difference reduction structure associated with a data link structure (e.g., the bezel reduction data link structure). Hereinafter, a light reflection difference reduction structure associated with the data link structure according to the aspects of the present disclosure will be described in detail with reference to FIGS. 11 to 15.

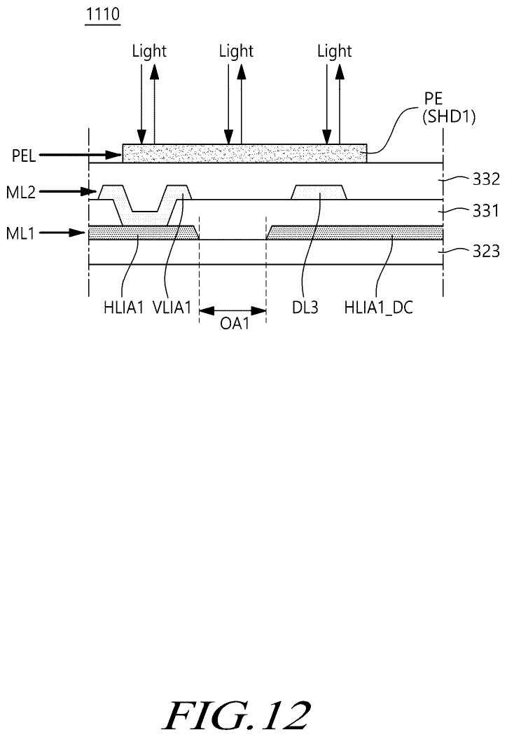

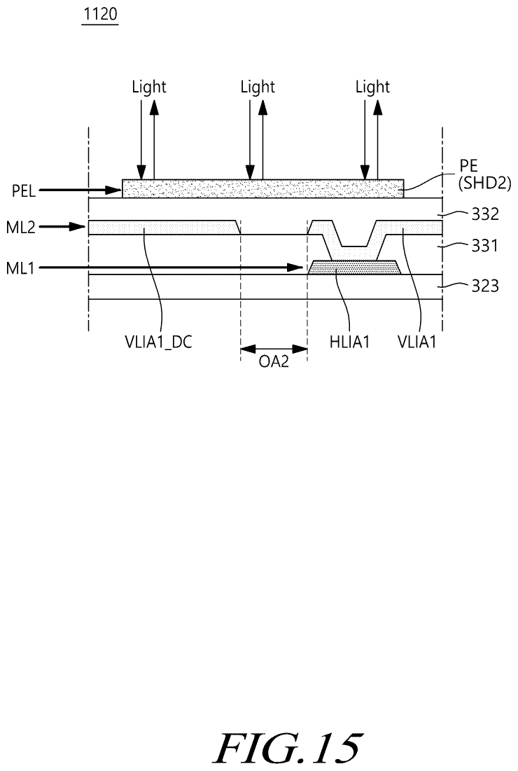

FIG. 11 illustrates an example structure capable of reducing a difference in reflected light (“light reflection difference reduction structure”) associated with the bezel reduction data link structure in the display panel 110 according to aspects of the present disclosure. FIGS. 12 to 14 illustrate example shielding structures configured in a first open area OA1 of a first metal layer ML1 in the display panel 110 according to aspects of the present disclosure. FIG. 15 illustrates an example shielding structure configured in a second open area OA2 of a second metal layer ML2 of the display panel 110 according to aspects of the present disclosure.

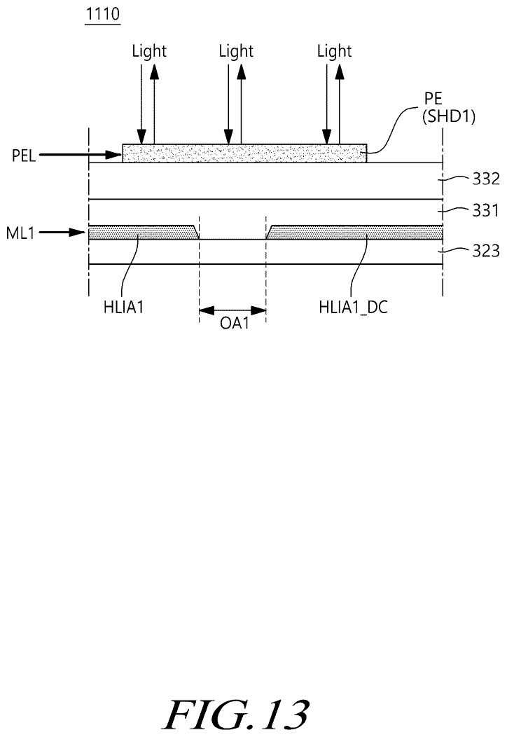

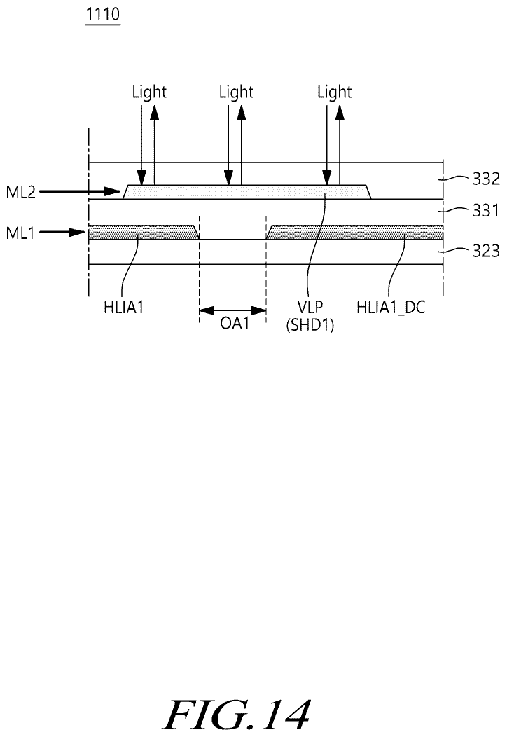

Similar to FIG. 8, FIG. 11 is an enlarged plan view for the area 600 of FIG. 6 in which the bezel reduction data link structure is configured. FIG. 12 is a cross-sectional view of an area 1110 including the first open area OA1 of the first metal layer ML1 of FIG. 11. FIGS. 13 and 14 illustrate other example shielding structures for the first open area OA1 of the first metal layer ML1. FIG. 15 is a cross-sectional view of an area 1120 including the second open area OA2 of the second metal layer ML2 of FIG. 11. In description that follows, for simplicity, discussions that are substantially the same as those described in FIGS. 8 to 10 will be omitted. Therefore, discussions will focus on different features.

Referring to FIGS. 11 to 15, in one or more aspects, the display apparatus 100 can include a substrate 111, a first signal line HLIA1 (also referred to as the first link line), a second signal line VLIA1 (also referred to as the second link line), and a first power line HLIA1_DC (also referred to as the first metal pattern), and a second power line VLIA1_DC (also referred to as the second metal pattern).

The first signal line HLIA1 can be disposed on the substrate 111. The first signal line HLIA1 can extend in a first direction (e.g., the row direction or the horizontal direction). The first signal line HLIA1 can be disposed in the active area AA allowing an image to be displayed.

The second signal line VLIA1 can be disposed over the substrate 111. The second signal line VLIA1 can extend in a second direction (e.g., the column direction or the vertical direction) different from the first direction. All or at least part of the second signal line VLIA1 can be disposed in the active area AA.

For example, the first signal line HLIA1 can be a first link line HLIA1, and the second signal line VLIA1 can be a second link line VLIA1.

The first signal line HLIA1 and the second signal line VLIA1 can be electrically connected.

The first power line HLIA1_DC can include the same first metal as the first signal line HLIA1 and can be disposed in the same row as the first signal line HLIA1. The first power line HLIA1_DC can be disposed such that the first power line HLIA1_DC is disconnected or spaced apart from the first signal line HLIA1.

The second power line VLIA1_DC can include the same second metal as the second signal line VLIA1 and can be disposed in the same column as the second signal line VLIA1. The second power line VLIA1_DC can be disposed such that the second power line VLIA1_DC is disconnected or spaced apart from the second signal line VLIA1.

The first power line HLIA1_DC can be a first metal pattern HLIA1_DC. The second power line VLIA1_DC can be a second metal pattern VLIA1_DC.

The first power line HLIA1_DC can extend in the first direction. The second power line VLIA1_DC can extend in the second direction.

The first power line HLIA1_DC and the second power line VLIA1_DC can be low power supply voltage lines VSSL to which the low power supply voltage VSS, which is the second common voltage, is applied.

The first signal line HLIA1 and the second signal line VLIA1 can be the first link line HLIA1 and the second link line VLIA1, respectively, which are electrically connected to a first data line DL1. The first power line HLIA1_DC and the second power line VLIA1_DC can be low power supply voltage lines VSSL to which the low power supply voltage VSS, which is the second common voltage, is applied.

For example, a signal (for example, a data voltage) whose voltage level can be variable per at least one or more frames or over time can be applied to the first signal line HLIA1 and the second signal line VLIA1, and a power signal (for example, the low power supply voltage VSS) whose voltage level does not vary per at least one or more frames or over time can be applied to the first power line HLIA1_DC and the second power line VLIA1_DC.

The first signal line HLIA1 can be disposed in the first metal layer ML1, and the second signal line VLIA1 can be disposed in the second metal layer ML2. For example, the second signal line VLIA1 can be located or disposed higher (further) from the substrate 111 than the first signal line HLIA1. That is to say that the second signal line VLIA1 may be located or disposed above the first signal line HLIA1.

Referring to FIGS. 12 to 14, in one or more aspects, the display apparatus 100 can further include a first shielding pattern SHD1 overlapping with the first open area OA1 where the first signal line HLIA1 and the first power line HLIA1_DC are disconnected. The first open area OA1 can be an area between the first signal line HLIA1 and the first power line HLIA1_DC. The first signal line HLIA1 and the first power line HLIA1_DC can be spaced apart from each other and disposed in the first metal layer ML1. In this case, the first open area OA1 can be an area where the first metal layer ML1 is disconnected, broken, or cut. At least a portion of the first shielding pattern SHD1 can overlap with the first open area OA1.

Referring to FIGS. 12 to 14, the first signal line HLIA1 and the first power line HLIA1_DC can be disposed in the first metal layer ML1, and the first shielding pattern SHD1 can be disposed in at least one of the second metal layer ML2 and a pixel electrode layer PEL.

Referring to FIG. 15, in one or more aspects, the display apparatus 100 can further include a second shielding pattern SHD2 overlapping with the second open area OA2 where the second signal line VLIA1 and the second power line VLIA1_DC are disconnected. The second open area OA2 can be an area between the second signal line VLIA1 and the second power line VLIA1_DC. The second signal line VLIA1 and the second power line VLIA1_DC can be spaced apart from each other and disposed in the second metal layer ML2. In this case, the second open area OA2 can be an area where the second metal layer ML2 is disconnected, broken, or cut. At least a portion of the second shielding pattern SHD2 can overlap with the second open area OA2.

Referring to FIG. 15, the second signal line VLIA1 and the second power line VLIA1_DC can be disposed in the second metal layer ML2, and the second shielding pattern SHD2 can be disposed in the pixel electrode layer PEL.

As shown in FIG. 12, a metal pattern disposed on a first planarization layer 331 can be a data line DL3 or another vertical line. For example, the another vertical line can be a first common driving voltage line VDDL, which transmits the first common driving voltage VDD, but aspects of the present disclosure are not limited thereto.

Hereinafter, the display panel 110 having the light reflection difference reduction structure associated with the bezel reduction data link structure according to the aspects of the present disclosure will be described in more detail.

Referring to FIG. 11, in one or more aspects, the display panel 110 can include the substrate 111 including the active area AA and the non-active area NA, a first data pad DP1, and the first data line DL1.

The active area AA of the display panel 110 can include a plurality of subpixels SP. The non-active area NA can be located or disposed outside of the active area AA. The non-active area NA can include a pad area PA. The first data pad DP1 can be disposed in the pad area PA. The first data line DL1 can be located or disposed in the active area AA. The first data line DL1 can extend in the column direction, and a data voltage can be applied to the first data line DL1.

The display panel 110 according to aspects of the present disclosure can have the bezel reduction data link structure. The display panel 110 can include the first link line HLIA1 and the second link line VLIA1 electrically connected to the first data line DL1.

The first link line HLIA1 can be electrically connected to the first data line DL1 and extend in the row direction. The second link line VLIA1 can electrically connect the first link line HLIA1 to the first data pad DP1 and extend in the column direction.

The first link line HLIA1 can be located or disposed in the active area AA allowing an image to be displayed. All or at least part of the second link line VLIA1 can be disposed in the active area AA. By applying these configurations, since all or most of the data link structure can be not disposed in the non-active area NA, the size of the bezel can be significantly reduced.

The first data line DL1 can be disposed in the second metal layer ML2. The first link line HLIA1 can be located or disposed in the first metal layer ML1, and the second link line VLIA1 can be located or disposed in the second metal layer ML2 different from the first metal layer ML1.

According to this configuration, horizontal lines (e.g., the first link line, the first metal pattern, and the like) extending in the horizontal direction (the row direction) can be disposed in the first metal layer ML1, and vertical lines (e.g., the second link line, the second metal pattern, and the like) extending in the vertical direction (the column direction) can be disposed in the second metal layer ML2.

The second metal layer ML2 can be located or disposed higher from the substrate 111 than the first metal layer ML1. For example, the first metal layer ML1 can be a first source-drain metal layer, and the second metal layer ML2 can be a second source-drain metal layer further from the substrate than the first metal layer ML1.

In one or more aspects, in association with the bezel reduction data link structure, the display panel 110 can further include the first metal pattern HLIA1_DC spaced apart from the first link line HLIA1, extending in the row direction, and disposed in the same row as the first link line HLIA1, and the second metal pattern VLIA1_DC spaced apart from the second link line VLIA1, extending in the column direction, and disposed in the same column as the second link line VLIA1.

For example, the first metal pattern HLIA1_DC can be located or disposed in the first metal layer ML1. The second metal pattern VLIA1_DC can be located or disposed in the second metal layer ML2.

As the first metal pattern HLIA1_DC is disposed in the same shape and arrangement as the first link line HLIA1, and the second metal pattern VLIA1_DC is disposed in the same shape and arrangement as the second link line VLIA1, the display panel 110 can have advantages of reducing display artifacts, such as image abnormalities, luminance disparities, color differences, and the like.

In an aspect, the first metal pattern HLIA1_DC and the second metal pattern VLIA1_DC can be electrically floating.

In another aspect, the low power supply voltage VSS, which is the second common driving voltage, can be applied to the first metal pattern HLIA1_DC and the second metal pattern VLIA1_DC.

The horizontal metal patterns including the first metal pattern HLIA1_DC and the vertical metal patterns including the second metal pattern VLIA1_DC may be configured as a mesh pattern in the active area AA. The horizontal metal patterns and the vertical metal patterns may be signal transmission paths for the low power supply voltage VSS in the active area AA. The horizontal metal patterns and the vertical metal patterns can supply the low power supply voltage VSS to the plurality of subpixels distributed in the active area AA. Arranging the horizontal metal patterns and the vertical metal patterns in a mesh shape may mean that the total width of the signal transmission paths for the low power supply voltage VSS can be expanded and the resistance of the signal transmission paths for the low power supply voltage VSS can be reduced. Thereby, the voltage drop of the low power supply voltage VSS can be reduced, and the transmission characteristics of the low power supply voltage VSS can be significantly improved.

In one or more aspects, the display panel 110 can include low power supply voltage lines VSSL for supplying the low power supply voltage VSS corresponding to a common driving voltage to a plurality of subpixels SP (see FIG. 2).

The low power voltage lines VSSL can be configured as horizontal metal patterns including the first metal pattern HLIA1_DC and vertical metal patterns including the second metal pattern VLIA1_DC. The horizontal metal patterns and the vertical metal patterns can intersect each other to form a mesh-patterned power line structure. The horizontal metal patterns and vertical metal patterns can be electrically connected to each other.

In one or more aspects, each of the plurality of subpixels SP can include a light emitting element ED including a pixel electrode PE, an intermediate layer EL, and a common electrode CE. The first metal pattern HLIA1_DC and the second metal pattern VLIA1_DC can be electrically connected to the common electrode CE to which the low power supply voltage VSS is applied. The low power supply voltage line VSSL may be electrically connected to at least one of the first metal pattern HLIA1_DC and the second metal pattern VLIA1_DC.

In addition, the low power supply voltage VSS, which is a signal having a constant voltage level, can be applied to the first metal pattern HLIA1_DC and the second metal pattern VLIA1_DC.

In one or more aspects, the display panel 110 can include, as a data link structure for a second data line DL2, a third link line HLIA2 and a fourth link line VLIA2 electrically connected to the second data line DL2.

The third link line HLIA2 can be electrically connected to the second data line DL2 and extend in the row direction. The fourth link line VLIA2 can electrically connect the third link line HLIA2 to a second data pad DP2 and extend in the column direction.

The third link line HLIA2 can be disposed in or at the active area AA configured to display an image. All or at least part of the fourth link line VLIA2 can be disposed in or at the active area AA. By applying these configurations, a bezel size needed for the data link structure can be reduced.

The third link line HLIA2 can be disposed in the first metal layer ML1. The fourth link line VLIA2 can be disposed in the second metal layer ML2 different from the first metal layer ML1.

In one or more aspects, in associated with the bezel reduction data link structure, the display panel 110 can further include a third metal pattern HLIA2_DC spaced apart from the third link line HLIA2, extending in the row direction, and disposed in the same row as the third link line HLIA2, and a fourth metal pattern VLIA2_DC spaced apart from the fourth link line VLIA2, extending in the column direction, and disposed in the same column as the fourth link line VLIA2.

The third metal pattern HLIA2_DC can be disposed in the first metal layer ML1. The fourth metal pattern VLIA2_DC can be disposed in the second metal layer ML2.

As the third metal pattern HLIA2_DC is disposed in the same shape and arrangement as the third link line HLIA2, and the fourth metal pattern VLIA2_DC is disposed in the same shape and arrangement as the fourth link line VLIA2, the display panel 110 can have advantages of reducing display artifacts, such as image abnormalities, luminance disparities, color differences, and the like.

In an aspect, the third metal pattern HLIA2_DC and the fourth metal pattern VLIA2_DC can be electrically floating.

In another aspect, the low power supply voltage VSS, which is the second common driving voltage, can be applied to the third metal pattern HLIA2_DC and the fourth metal pattern VLIA2_DC.

The horizontal metal patterns including the third metal pattern HLIA2_DC and the vertical metal patterns including the fourth metal pattern VLIA2_DC may be configured as a mesh pattern in the active area AA. The horizontal metal patterns and the vertical metal patterns may be signal transmission paths for the low power supply voltage VSS in the active area AA. The horizontal metal patterns and the vertical metal patterns can supply the low power supply voltage VSS to the plurality of subpixels distributed in the active area AA. Arranging the horizontal metal patterns and the vertical metal patterns in a mesh shape may mean that the total width of the signal transmission paths for the low power supply voltage VSS can be expanded and the resistance of the signal transmission paths for the low power supply voltage VSS can be reduced. Thereby, the voltage drop of the low power supply voltage VSS can be reduced, and the transmission characteristics of the low power supply voltage VSS can be significantly improved.

In one or more aspects, the display panel 110 can include one or more low power supply voltage lines VSSL configured to supply the low power supply voltage VSS corresponding to a common driving voltage to a plurality of subpixels SP (see FIG. 2).

The low power supply voltage lines VSSL can be electrically connected to the third metal pattern HLIA2_DC and the fourth metal pattern VLIA2_DC.

In one or more aspects, each of the plurality of subpixels SP can include a light emitting element ED including a pixel electrode PE, an intermediate layer EL, and a common electrode CE, and the third metal pattern HLIA2_DC and the fourth metal pattern VLIA2_DC can be electrically connected to the common electrode CE to which the low power supply voltage VSS is applied.

In one or more aspects, the low power supply voltage VSS, which is a signal having a constant voltage level, can be applied to the third metal pattern HLIA2_DC and the fourth metal pattern VLIA2_DC.

The display panel 110 according to aspects of the present disclosure can include the light reflection difference reduction structure associated with the bezel reduction data link structure.

The light reflection difference reduction structure associated with the bezel reduction data link structure can serve to reduce a difference in reflected light caused by the first open area OA1 in the first metal layer ML1 and the second open area OA2 in the second metal layer ML2.

The light reflection difference reduction structure associated with the bezel reduction data link structure can be referred to as a shielding structure.

Referring to FIGS. 11 to 14, in one or more aspects, the display panel 110 can further include a first shielding pattern SHD1 overlapping with the first open area OA1 where the first metal pattern HLIA1_DC and the first link line HLIA1 are spaced apart from each other.

Referring to FIGS. 12 and 13, the first shielding pattern SHD1 can be disposed in the pixel electrode layer PEL and overlap with the first open area OA1 where the first metal pattern HLIA1_DC and the first link line HLIA1 are spaced apart from each other.

Referring to FIGS. 12 and 13, the first shielding pattern SHD1 can be disposed in the pixel electrode layer PEL, and be a pixel electrode PE in the light emitting element ED or include the same material as the pixel electrode PE. For example, the first shielding pattern SHD1 can include the same pixel electrode material as the pixel electrode PE.

Referring to FIGS. 12 and 13, the first metal pattern HLIA1_DC and the first link line HLIA1 can be disposed in the first metal layer ML1, and the pixel electrode layer PEL can be a metal layer and can be disposed higher than the first metal layer ML1. That is to say that the pixel electrode layer PEL may be further from the substrate than the first metal layer ML1.

Referring to FIG. 14, in an aspect, the first shielding pattern SHD1 can be a metal pattern VLP disposed in the second metal layer ML2 according to a location of the first open area OA1 where the first metal pattern HLIA1_DC and the first link line HLIA1 are spaced apart in the display panel 110. The first open area OA1 can be an area between the first metal pattern HLIA1_DC and the first link line HLIA1. The first metal pattern HLIA1_DC and the first link line HLIA1 can be spaced apart from each other and disposed in the first metal layer ML1. In this case, the first open area OA1 can be an area where the first metal layer ML1 is disconnected, broken, or cut. At least a portion of the first shielding pattern SHD1 can overlap with the first open area OA1.

Referring to FIG. 14, the first shielding pattern SHD1 can be disposed in the same metal layer as a vertical line extending in the column direction. This vertical line can include the first data line DL1, the second link line VLIA1, the first common driving voltage line VDDL, and the like.

In another aspect, the first shielding pattern SHD1 can include all of the metal pattern VLP in the second metal layer ML2 and a metal pattern disposed in the pixel electrode layer PEL according to a location of the first open area OA1 where the first metal pattern HLIA1_DC and the first link line HLIA1 are spaced apart in the display panel 110. The metal pattern disposed in the pixel electrode layer PEL can include all of the pixel electrode PE and a pixel electrode material pattern.

The first open area OA1 where the first metal pattern HLIA1_DC and the first link line HLIA1 are spaced apart can be one of a plurality of first open areas OA1 located or disposed in the first metal layer ML1. A plurality of first shielding patterns SHD1 can be disposed such that the plurality of first shielding patterns SHD1 overlap with the plurality of first open areas OA1 in the first metal layer ML1.

As described above, referring to FIGS. 11 to 15 and FIG. 7, the first open area OA1 of the first metal layer ML1 can be present at a boundary of the first area (Area A) and the second area (Area B) among the three areas (A, B, C) defined in the active area AA by the bezel reduction data link structure.

Accordingly, the plurality of first shielding patterns SHD1 overlapping with the plurality of first open areas OA1 being present in the first metal layer ML1 can be disposed in the direction (e.g., a diagonal direction) of the boundary between the first area (Area A) and the second area (Area B) running at a pre-defined (or consistent) angle to the row direction or the column direction. The plurality of first shielding patterns SHD1 may be disposed at a pre-defined angle with respect to the column direction or the row direction. Accordingly, the plurality of first shielding patterns SHD1 can be located along and aligned with the first slant lines SLT_DL.

Referring to FIGS. 11 and 15, in one or more aspects, the display panel 110 can further include a second shielding pattern SHD2 overlapping with the second open area OA2 where the second metal pattern VLIA1_DC and the second link line VLIA1 are spaced apart from each other. The second open area OA2 can be an area between the second metal pattern VLIA1_DC and the second link line VLIA1. The second metal pattern VLIA1_DC and the second link line VLIA1 can be spaced apart from each other and disposed in the second metal layer ML2. In this case, the second open area OA2 can be an area where the second metal layer ML2 is disconnected, broken, or cut. At least a portion of the second shielding pattern SHD2 can overlap with the second open area OA2.

Referring to FIG. 15, the second shielding pattern SHD2 can include a metal pattern disposed in the pixel electrode layer PEL. This metal pattern disposed in the pixel electrode layer PEL can be the pixel electrode PE or can include the same material as the pixel electrode PE. For example, the second shielding pattern SHD2 can include the same pixel electrode material as the pixel electrode PE.

The second open area OA2 where the second metal pattern VLIA1_DC and the second link line VLIA1 are spaced apart can be one of a plurality of second open areas OA2 located or disposed in the second metal layer ML2. A plurality of second shielding patterns SHD2 can be disposed such that the plurality of second shielding patterns SHD2 overlap with the plurality of second open areas OA2 in the second metal layer ML2.

Referring to FIGS. 11 to 15 and FIG. 7, the first open area OA1 of the first metal layer ML1 and the second open area OA2 of the second metal layer ML2 can be present at a boundary of the second area (Area B) and the third area (Area C) among the three areas (A, B, C) defined in the active area AA by the bezel reduction data link structure.

Accordingly, the plurality of second shielding patterns SHD2 overlapping with the plurality of second open areas OA2 being present in the second metal layer ML2 can be disposed in the direction (e.g., a diagonal direction) of the boundary between the second area (Area B) and the third area (Area C) running at a pre-defined (consistent) angle to the row direction or the column direction. The plurality of second shielding patterns SHD2 may be disposed at a pre-defined angle with respect to the column direction or the row direction. Accordingly, the plurality of second shielding patterns SHD2 can be located along and aligned with the second slant lines SLT_LIA.

The first metal layer ML1 and the second metal layer ML2 in the display panel 110 will be briefly described with reference to FIG. 3.

In the display panel 110, horizontal lines extending in the horizontal direction (the row direction) can be disposed in the first metal layer ML1, and vertical lines extending in the vertical direction (the column direction) can be disposed in the second metal layer ML2.

Referring to FIG. 3, each of a plurality of subpixels SP can include a light emitting element ED and two or more transistors (TFT1 and TFT2). The two or more transistors (TFT1 and TFT2) can include source electrodes (E1b and E2b) and drain electrodes (E1c and E2c).

The source electrodes (E1b and E2b) and the drain electrodes (E1c and E2c) can include a first metal in the first link line HLIA1 and the first metal pattern HLIA1_DC or may include a metal layer in which the first link line HLIA1 and the first metal pattern HLIA1_DC are disposed. The first metal can be a metal configuring the first metal layer ML1. The first link line HLIA1 and the first metal pattern HLIA1_DC can be included in a horizontal line. As described above, the first link line HLIA1 and the first metal pattern HLIA1_DC may be disposed together with the source electrodes (E1b and E2b) and the drain electrodes (E1c and E2c) in the first metal layer ML1. During the panel manufacturing process, the first link line HLIA1 and the first metal pattern HLIA1_DC may be formed together when the source electrodes E1b and E2b and the drain electrodes E1c and E2c are formed. Accordingly, there is no need to add a separate process to form the first link line HLIA1 and the first metal pattern HLIA1_DC.

Referring to FIGS. 11 to 15 and FIG. 3, the light emitting element ED can include the pixel electrode PE, the intermediate layer EL, and the common electrode CE, and the relay electrode RE can electrically connect the pixel electrode PE to the source electrode E1b or drain electrode E1c of the first transistor TFT1 of two or more transistors (TFT1 and TFT2).

The relay electrode RE can include a second metal in the second link line VLIA1 and the second metal pattern VLIA1_DC, or may include a metal layer in which the second link line VLIA1 and the second metal pattern VLIA1_DC are disposed. The second metal can be a metal configuring the second metal layer ML2. The second link line VLIA1 and the second metal pattern VLIA1_DC can be included in a vertical line. As described above, the second link line VLIA1 and the second metal pattern VLIA1_DC may be disposed together with the relay electrode RE in the second metal layer ML2. During the panel manufacturing process, the second link line VLIA1 and the second metal pattern VLIA1_DC may be formed together when the relay electrode RE is formed. Accordingly, there is no need to add a separate process to form the second link line VLIA1 and the second metal pattern VLIA1_DC.

The first data line DL1, which is one of vertical line, can also be disposed in the second metal layer ML2.

A display apparatus according to aspects of the present disclosure are described below.

According to some aspects of the present disclosure, a display apparatus can include a substrate including a display area having a plurality of subpixels, a first data line disposed at the display area and extending in a column direction, a first link line disposed at the display area, electrically connected to the first data line, and extending in a row direction, a second link line disposed at the display area and extending in the column direction, a first metal pattern spaced apart from the first link line and extending in the row direction, and a second metal pattern spaced apart from the second link line and extending in the column direction.

In one or more aspects, the first link line can be disposed in the display area. All or at least part of the second link line can be disposed in the display area.

In one or more aspects, the first link line and the first metal pattern can be disposed in a first metal layer. The second link line and the second metal pattern can be disposed in a second metal layer different from the first metal layer.

In one or more aspects, the second metal layer can be disposed further from the substrate than the first metal layer.

In one or more aspects, the display apparatus can further include a low power supply voltage line configured to supply a low power supply voltage to the plurality of subpixels. The low power supply voltage line can be electrically connected to the first metal pattern and the second metal pattern. For example, the lower power supply voltage can correspond to a common driving voltage.

In one or more aspects, each of the plurality of subpixels can include a light emitting element including a pixel electrode, an intermediate layer, and a common electrode. The first metal pattern and the second metal pattern can be electrically connected to the common electrode.

In one or more aspects, the display apparatus can further include a first open area between the first metal pattern and the first link line, and a first shielding pattern overlapping with the first open area.

In one or more aspects, the first shielding pattern can be the pixel electrode or include a same material as the pixel electrode.

In one or more aspects, the first shielding pattern can be a metal pattern disposed in the second metal layer. For example, the first shielding pattern can be a metal pattern disposed in the second metal layer in which the second link line and the second metal pattern are disposed. The first shielding pattern can be a metal pattern disposed in a metal layer in which the second link line and the second metal pattern are disposed.

In one or more aspects, the first shielding pattern can be disposed in a same metal layer as a vertical line extending in the column direction.

In one or more aspects, the first open area can be one of a plurality of first open areas disposed in the first metal layer. For example, the first open area can be one of a plurality of first open areas disposed in a first metal layer in which the first link line and the first metal pattern are disposed.

In one or more aspects, a plurality of first shielding patterns can overlap with the plurality of first open areas.

In one or more aspects, the plurality of first shielding patterns can be disposed at a pre-defined angle with respect to the column direction or the row direction (e.g., a diagonal direction).

In one or more aspects, the display apparatus can further include a second open area between the second metal pattern and the second link line, and a second shielding pattern overlapping with the second open area.

In one or more aspects, the second shielding pattern can be the pixel electrode or a pattern including a same material as the pixel electrode.

In one or more aspects, the second open area can be one of a plurality of second open areas disposed in the second metal layer. For example, the second open area can be one of a plurality of second open areas disposed in the second metal layer in which the second link line and the second metal pattern are disposed.

In one or more aspects, a plurality of second shielding patterns can overlap with the plurality of second open areas.

In one or more aspects, the plurality of second shielding patterns can be disposed at a pre-defined angle with respect to the column direction or the row direction (e.g., a diagonal direction).

In one or more aspects, the first data line can be disposed in a metal layer. For example, the first data line can be disposed in a metal layer (second metal layer) in which the second link line and the second metal pattern are disposed.

In one or more aspects, each of the plurality of subpixels can include a light emitting element and two or more transistors, and each of the two or more transistors can include a source electrode or a drain electrode.

In one or more aspects, respective source or drain electrodes included in the two or more transistors can include a metal layer. For example, respective source or drain electrodes included in the two or more transistors can include a metal layer in which the first link line and the first metal pattern are disposed.

In one or more aspects, the display apparatus can further include a connection electrode (relay electrode) configured to electrically connect the pixel electrode with a source electrode or a drain electrode of a first transistor among the two or more transistors.

In one or more aspects, the connection electrode can include a metal layer. For example, the connection electrode can include a metal layer in which the second link line and the second metal pattern are disposed.

In one or more aspects, the substrate can include a non-display area outside of the display area. The non-display area can include a pad area having at least one pad. The second link line can electrically connect the first link line to the pad.

In one or more aspects, the display area can include a first area in which horizontal link lines extending in the row direction and vertical link lines extending in the column direction are not disposed, a second area including the horizontal link lines, and a third area including the vertical link lines. The horizontal link lines can include the first link line (the first signal line), and the vertical link lines can include the second link line (the second signal line).

In one or more aspects, the display apparatus can further include a first open area between the first metal pattern and the first link line. The first open area can be present at a boundary of the first area and the second area.

In one or more aspects, the display apparatus can further include a second open area between the second metal pattern and the second link line. The first open area and the second open area can be present at a boundary of the second area and the third area.

In one or more aspects, the first metal pattern can be disposed in the same shape as the first link line, and the second metal pattern can be disposed in the same shape as the second link line.

In one or more aspects, the low power voltage line can be configured in horizontal metal patterns including the first metal pattern and vertical metal patterns including the second metal pattern.

In one or more aspects, the display apparatus can further include a third link line disposed in the first metal layer, a fourth link line disposed in the second metal layer, a third metal pattern spaced apart from the third link line, extending in the row direction, and disposed in the same row as the third link line, and fourth metal pattern spaced apart from the fourth link line, extending in the column direction, and disposed in the same column as the fourth link line.

In one or more aspects, a display apparatus can include a substrate, a first signal line disposed on the substrate and extending in a first direction, and a first power line including a same first metal as the first signal line and spaced apart from the first signal line. The display apparatus can further include a second signal line disposed on the substrate and extending in a second direction different from the first direction, and a second power line including a same second metal as the second signal line and spaced apart from the second signal line.

In one or more aspects, the first signal line can be disposed at a display area configured to display an image. All or some of the second signal line can be disposed at the display area.

In one or more aspects, the first signal line can be electrically connected to the second signal line.

In one or more aspects, the first power line can extend in the first direction. The second power line can extend in the second direction.

In one or more aspects, a signal whose voltage level is variable over time (e.g., per at least one or more frames) can be applied to the first signal line and the second signal line.

In one or more aspects, a power signal whose voltage level does not vary over time (e.g., per at least one or more frames) can be applied to the first power line and the second power line.

In one or more aspects, the second signal line can be disposed further from the substrate than the first signal line.

In one or more aspects, the display apparatus can further include a first shielding pattern overlapping with a first open area between the first signal line and the first power line.

In one or more aspects, the display apparatus can further include a second shielding pattern overlapping with a second open area between the second signal line and the second power line.

In one or more aspects, the first signal line can be disposed at a display area configured to display an image, and all or some of the second signal line can be disposed at the display area.

In one or more aspects, the first signal line can be electrically connected to the second signal line.

In one or more aspects, the first power line can extend in the first direction, and the second power line can extend in the second direction.

In one or more aspects, the first signal line and the first power line can be disposed in a first metal layer. The second signal line and the second power line can be disposed in a second metal layer different from the first metal layer.

In one or more aspects, the display apparatus can further include a first shielding pattern overlapping with a first open area between the first signal line and the first power line. The first shielding pattern can be disposed in at least one of the second metal layer and a layer in which a pixel electrode is disposed.

In one or more aspects, the display apparatus can further include a second shielding pattern overlapping with a second open area between the second signal line and the second power line. The second shielding pattern can be disposed in the layer in which the pixel electrode is disposed.

In one or more aspects, a display apparatus can comprise a substrate including a display area having a plurality of subpixels, a first data line disposed at the display area and extending in a column direction, a first link line disposed at the display area, electrically connected to the first data line, and extending in a row direction, a second link line disposed at the display area, electrically connected to the first link line, and extending in the column direction, a first metal pattern spaced apart from the first link line and colinear with the first link line. At least one of the plurality of subpixels can overlap at a location where the first link line connects to the second link line.

According to the aspects described herein, a display apparatus can be provided with a data link structure capable of reducing the bezel size of a display panel.

According to the aspects, a display apparatus can be provided with a bezel reduction data link structure capable of improving image quality.

According to the aspects, a display apparatus can be provided with a bezel reduction data link structure capable of improving the performance of transmitting a common driving voltage.

According to the aspects, a display apparatus can be provided with a bezel reduction data link structure capable of reducing a difference in reflected light.

According to the aspects, a display apparatus and/or a display panel can be provided with a reduced weight by reducing the bezel size of the display panel using an improved data link structure.

A display apparatus according to the aspects of the present disclosure can be applied to mobile devices, video phones, smart watches, watch phones, wearable apparatuses, foldable apparatuses, rollable apparatuses, bendable apparatuses, flexible apparatuses, stretchable apparatuses, curved apparatuses, sliding apparatuses, variable apparatuses, electronic notebooks, e-books, portable multimedia players (PMP), personal digital assistants (PDA), MP3 players, mobile medical apparatuses, desktop PCs, laptop PCs, netbook computers, workstations, navigation apparatuses, car navigation apparatuses, vehicle display apparatuses, vehicle apparatuses, theater apparatuses, theater display apparatuses, televisions, wallpaper apparatuses, signage apparatuses, game apparatuses, notebook computers, monitors, cameras, camcorders, and home appliances, and the like.

It will be apparent to those skilled in the art that various modifications and variations can be made in the present disclosure without departing from the scope of the disclosures. Thus, it is intended that the present disclosure covers the modifications and variations of this disclosure provided they come within the scope of the appended claims and their equivalents.

What is claimed is:

1. A display apparatus, comprising:
a substrate including a display area having a plurality of subpixels;
a first data line disposed at the display area and extending in a column direction;
a first link line disposed at the display area, electrically connected to the first data line, and extending in a row direction;
a second link line disposed at the display area and extending in the column direction;
a first metal pattern spaced apart from the first link line and extending in the row direction; and
a second metal pattern spaced apart from the second link line and extending in the column direction.

2. The display apparatus of claim 1, wherein the first link line and the first metal pattern are disposed in a first metal layer, and the second link line and the second metal pattern are disposed in a second metal layer different from the first metal layer.

3. The display apparatus of claim 2, wherein the second metal layer is disposed further from the substrate than the first metal layer.

4. The display apparatus of claim 1, further comprising a low power supply voltage line configured to supply a low power supply voltage to the plurality of subpixels,
wherein the low power supply voltage line is electrically connected to at least one of the first metal pattern and the second metal pattern.

5. The display apparatus of claim 1, wherein each of the plurality of subpixels comprises a light emitting element including a pixel electrode, an intermediate layer, and a common electrode, and
wherein the first metal pattern and the second metal pattern are electrically connected to the common electrode.

6. The display apparatus of claim 1, further comprising:
a first open area between the first metal pattern and the first link line; and
a first shielding pattern overlapping with the first open area.

7. The display apparatus of claim 6, wherein each of the plurality of subpixels comprises a light emitting element including a pixel electrode, an intermediate layer, and a common electrode, and
wherein the first shielding pattern is the pixel electrode or includes a same material as the pixel electrode.

8. The display apparatus of claim 6, wherein the first shielding pattern is a metal pattern disposed in a metal layer in which the second link line and the second metal pattern are disposed.

9. The display apparatus of claim 6, wherein the first shielding pattern is disposed in a same metal layer as a vertical line extending in the column direction.

10. The display apparatus of claim 6, wherein the first open area is one of a plurality of first open areas disposed in a metal layer in which the first link line and the first metal pattern are disposed, and
wherein a plurality of first shielding patterns including the first shielding pattern overlap with the plurality of first open areas, and the plurality of first shielding patterns are disposed at a pre-defined angle with respect to the column direction or the row direction.

11. The display apparatus of claim 1, further comprising:
a second open area between the second metal pattern and the second link line; and
a second shielding pattern overlapping with the second open area.

12. The display apparatus of claim 11, wherein each of the plurality of subpixels comprises a light emitting element including a pixel electrode, an intermediate layer, and a common electrode, and
wherein the second shielding pattern is the pixel electrode or includes a same material as the pixel electrode.

13. The display apparatus of claim 11, wherein the second open area is one of a plurality of second open areas disposed in a metal layer in which the second link line and the second metal pattern are disposed, and
wherein a plurality of second shielding patterns including the second shielding pattern overlap with the plurality of second open areas, and the plurality of second shielding patterns are disposed at a pre-defined angle with respect to the column direction or the row direction.

14. The display apparatus of claim 1, wherein the first data line is disposed in a metal layer in which the second link line and the second metal pattern are disposed.

15. The display apparatus of claim 1, wherein each of the plurality of subpixels includes a light emitting element and two or more transistors,
wherein the light emitting element includes a pixel electrode, an intermediate layer, and a common electrode, and
wherein respective source or drain electrodes in the two or more transistors includes a metal layer in which the first link line and the first metal pattern are disposed.

16. The display apparatus of claim 15, further comprising a connection electrode configured to electrically connect the pixel electrode with a source electrode or a drain electrode of a first transistor among the two or more transistors,
wherein the connection electrode includes a metal layer in which the second link line and the second metal pattern are disposed.

17. The display apparatus of claim 1, wherein the substrate comprises a non-display area outside of the display area,
wherein the non-display area includes a pad area having a pad, and
wherein the second link line electrically connects the first link line to the pad.

18. The display apparatus of claim 1, wherein the display area comprises:
a first area in which horizontal link lines extending in the row direction and vertical link lines extending in the column direction are not disposed;
a second area including the horizontal link lines; and
a third area including the vertical link lines, and
wherein the horizontal link lines include the first link line, and the vertical link lines include the second link line.

19. The display apparatus of claim 18, further comprising:
a first open area between the first metal pattern and the first link line,
wherein the first open area is present at a boundary of the first area and the second area.

20. The display apparatus of claim 19, further comprising:
a second open area between the second metal pattern and the second link line,
wherein the first open area and the second open area are present at a boundary of the second area and the third area.

21. The display apparatus of claim 1, wherein the first metal pattern is disposed in the same shape as the first link line, and the second metal pattern is disposed in the same shape as the second link line.

22. The display apparatus of claim 4, wherein the low power voltage line is configured in horizontal metal patterns including the first metal pattern and vertical metal patterns including the second metal pattern.

23. The display apparatus of claim 2, further comprising:
a third link line disposed in the first metal layer;
a fourth link line disposed in the second metal layer;
a third metal pattern spaced apart from the third link line, extending in the row direction, and disposed in the same row as the third link line, and
a fourth metal pattern spaced apart from the fourth link line, extending in the column direction, and disposed in the same column as the fourth link line.

24. A display apparatus, comprising:
a substrate;
a first signal line disposed on the substrate and extending in a first direction;
a first power line including a same first metal as the first signal line and spaced apart from the first signal line;
a second signal line disposed on the substrate and extending in a second direction different from the first direction; and
a second power line including a same second metal as the second signal line and spaced apart from the second signal line.

25. The display apparatus of claim 24, wherein a signal, a voltage level of which is variable over time, is applied to the first signal line and the second signal line, and a power signal, a voltage level of which does not vary over time, is applied to the first power line and the second power line.

26. The display apparatus of claim 24, further comprising a first shielding pattern overlapping with a first open area in which the first signal line and the first power line are disconnected.

27. The display apparatus of claim 24, further comprising a second shielding pattern overlapping with a second open area in which the second signal line and the second power line are disconnected.

28. The display apparatus of claim 24, wherein the first signal line is disposed at a display area configured to display an image, and all or some of the second signal line is disposed at the display area.

29. The display apparatus of claim 24, wherein the first signal line is electrically connected to the second signal line.

30. The display apparatus of claim 24, wherein the first power line extends in the first direction, and the second power line extends in the second direction.

31. The display apparatus of claim 24, wherein the first signal line and the first power line are disposed in a first metal layer, and the second signal line and the second power line are disposed in a second metal layer different from the first metal layer.

32. The display apparatus of claim 31, further comprising:
a first shielding pattern overlapping with a first open area between the first signal line and the first power line,
wherein the first shielding pattern is disposed in at least one of the second metal layer and a layer in which a pixel electrode is disposed.

33. The display apparatus of claim 32, further comprising:
a second shielding pattern overlapping with a second open area between the second signal line and the second power line,
wherein the second shielding pattern is disposed in the layer in which the pixel electrode is disposed.
